(19) United States
(12) Patent Application Publication
(10) Pub. No.: US 2026/0047079 A1
(43) Pub. Date: Feb. 12, 2026

(54) SEMICONDUCTOR MEMORY DEVICE

(71) Applicant: Samsung Electronics Co., Ltd., Suwon-si (KR)

(72) Inventors: Taekyong KIM, Suwon-si (KR); Taejin PARK, Suwon-si (KR); Hyeonkyu LEE, Suwon-si (KR); Sungsoo YIM, Suwon-si (KR); Hyunmin CHO, Suwon-si (KR)

(73) Assignee: Samsung Electronics Co., Ltd., Suwon-si (KR)

(21) Appl. No.: 19/037,883

(22) Filed: Jan. 27, 2025

(30) Foreign Application Priority Data
Aug. 7, 2024 (KR) 10-2024-0105752

(51) Int. Cl. H10B 12/00

(52) U.S. Cl. CPC H10B 12/482; H10B 12/315; H10B 12/485; H10B 12/488; H10B 12/50

(57) ABSTRACT

A semiconductor memory device includes bit lines including first bit lines and second bit lines, bit line contacts connected to the second bit lines, word lines on the bit lines and the bit line contacts, back gate electrodes separated from the word lines, channel patterns each extending in a vertical direction between a word line among the word lines and a back gate electrode among the back gate electrodes, contact plugs each connected to each of the channel patterns, and capacitors including lower electrodes connected to the contact plugs, an upper electrode on the lower electrodes, and a capacitor dielectric film between the lower electrodes and the upper electrode.

### CROSS-REFERENCE TO RELATED APPLICATION

This application is based on and claims priority under 35 U.S.C. § 119 to Korean Patent Application No. 10-2024-0105752, filed on Aug. 7, 2024, in the Korean Intellectual Property Office, the disclosure of which is incorporated by reference herein in its entirety.

### BACKGROUND

Some example embodiments relate to a semiconductor memory device. More particularly, the inventive concept relates to a semiconductor memory device including a vertical channel transistor.

With the high integration density of semiconductor memory devices, semiconductor devices included in the semiconductor memory devices are becoming highly integrated. To integrate semiconductor devices with a high level of integration, vertical channel transistors vertically arranged on semiconductor substrates rather than planar channel transistors arranged flat on semiconductor substrates are being introduced.

### SUMMARY

Some example embodiments provide a semiconductor memory device including a vertical channel transistor having increased operational reliability.

According to some example embodiments, there is provided a semiconductor memory device including a bit line structure including a plurality of bit lines and a plurality of bit line contacts, the plurality of bit lines extending in a first horizontal direction and spaced apart from each other in a second horizontal direction perpendicular to the first horizontal direction, a capacitor structure including a plurality of contact plugs and a plurality of capacitors, the plurality of capacitors including a plurality of lower electrodes connected to the plurality of contact plugs, an upper electrode on the plurality of lower electrodes, and a capacitor dielectric film between the plurality of lower electrodes and the upper electrode, and a channel structure including a plurality of vertical channel transistors, the plurality of vertical channel transistors including a plurality of channel patterns, a plurality of word lines, and a plurality of back gate electrodes, the plurality of channel patterns between the plurality of bit lines and the plurality of bit line contacts and extending in a vertical direction, and the plurality of word lines and the plurality of back gate electrodes extending in the second horizontal direction between the plurality of bit lines and the plurality of bit line contacts and having the plurality of channel patterns among the plurality of word lines and the plurality of back gate electrodes. The bit line structure, the capacitor structure, and the channel structure are stacked, the plurality of bit lines include a plurality of first bit lines connected to at least some of the plurality of channel patterns and a plurality of second bit lines connected to at least other channel patterns of the plurality of channel patterns, the plurality of first bit lines and the plurality of second bit lines alternately arranged in the second horizontal direction in a plan view, at least a portion of each of the plurality of first bit lines and at least a portion of each of the plurality of second bit lines at different vertical levels, and the plurality of bit line contacts are at a same vertical level as at least the portion of each of the plurality of first bit lines, and the plurality of bit line contacts connect the plurality of second bit lines to the other channel patterns.

Alternatively or additionally according to some example embodiments, there is provided a semiconductor memory device including a plurality of bit lines extending in a first horizontal direction and spaced apart from each other in a second horizontal direction perpendicular to the first horizontal direction, the plurality of bit lines including a plurality of first bit lines and a plurality of second bit lines alternating with the plurality of first bit lines in the second horizontal direction in a plan view, a plurality of bit line contacts connected to the plurality of second bit lines, a plurality of word lines on the plurality of bit lines and the plurality of bit line contacts and extending in the second horizontal direction, a plurality of back gate electrodes separated from the plurality of word lines and extending in the second horizontal direction, a plurality of channel patterns each extending in a vertical direction between a word line among the plurality of word lines and a back gate electrode among the plurality of back gate electrodes and having a first end and a second end opposite to the first end, the word line and the back gate electrode adjacent to each other, and the second end connected to at least one of the plurality of first bit lines or one of the plurality of bit line contacts, a plurality of contact plugs each connected to the first end of each of the plurality of channel patterns, and a plurality of capacitors including a plurality of lower electrodes connected to the plurality of contact plugs, an upper electrode on the plurality of lower electrodes, and a capacitor dielectric film between the plurality of lower electrodes and the upper electrode.

Alternatively or additionally according to some example embodiments, there is provided a semiconductor memory device including a bit line structure including a plurality of bit lines, a plurality of bit line contacts, and a first interlayer insulating layer, the plurality of bit lines extending in a first horizontal direction and spaced apart from each other in a second horizontal direction perpendicular to the first horizontal direction, the plurality of bit lines including a plurality of first bit lines and a plurality of second bit lines alternating with the plurality of first bit lines in the second horizontal direction in a plan view, the plurality of bit line contacts connected to the plurality of second bit lines, and the first interlayer insulating layer surrounding the plurality of bit lines and the plurality of bit line contacts and filling all space between the plurality of bit lines, a capacitor structure including a plurality of contact plugs, a second interlayer insulating layer surrounding the plurality of contact plugs, and a plurality of capacitors including a plurality of lower electrodes connected to the plurality of contact plugs, an upper electrode on the plurality of lower electrodes, and a capacitor dielectric film between the plurality of lower electrodes and the upper electrode, a channel structure including a plurality of vertical channel transistors, the plurality of vertical channel transistors including a plurality of channel patterns, a plurality of word lines, and a plurality of back gate electrodes, the plurality of channel patterns between the plurality of bit lines and the plurality of bit line contacts and extending in a vertical direction, and the plurality of word lines and the plurality of back gate electrodes extending in the second horizontal direction and having the plurality of channel patterns among the plurality of word lines and the plurality of back gate electrodes, and a peripheral circuit structure at least partly overlapped by a memory cell region corresponding to the bit line structure, the capacitor structure, and the channel structure and including a peripheral circuit transistor, The bit line structure, the capacitor structure, the channel structure, and the peripheral circuit structure are stacked, at least a portion of each of the plurality of first bit lines and at least a portion of each of the plurality of second bit lines are at different vertical levels, and the plurality of bit line contacts are at a same vertical level as at least the portion of each of the plurality of first bit lines.

### BRIEF DESCRIPTION OF THE DRAWINGS

Embodiments will be more clearly understood from the following detailed description taken in conjunction with the accompanying drawings in which:

FIG. 1 is a plane layout illustrating a semiconductor memory device according to some example embodiments, and FIGS. 2A to 2D are cross-sectional views of the semiconductor memory device according to some example embodiments;

FIGS. 3A to 3C are enlarged views of a region III in FIG. 2C;

FIG. 4 is a cross-sectional view of a semiconductor memory device according to some example embodiments;

FIGS. 5A to 8B are cross-sectional views illustrating a method of manufacturing a bit line structure included in a semiconductor memory device, according to some example embodiments;

FIGS. 9A to 12B are cross-sectional views illustrating a method of manufacturing a bit line structure included in a semiconductor memory device, according to some example embodiments;

FIGS. 13A to 13D are cross-sectional views of the semiconductor memory device according to some example embodiments; and

FIGS. 14 to 17 are flowcharts of methods of manufacturing a semiconductor memory device, according to some example embodiments.

### DETAILED DESCRIPTION OF SOME EXAMPLE EMBODIMENTS

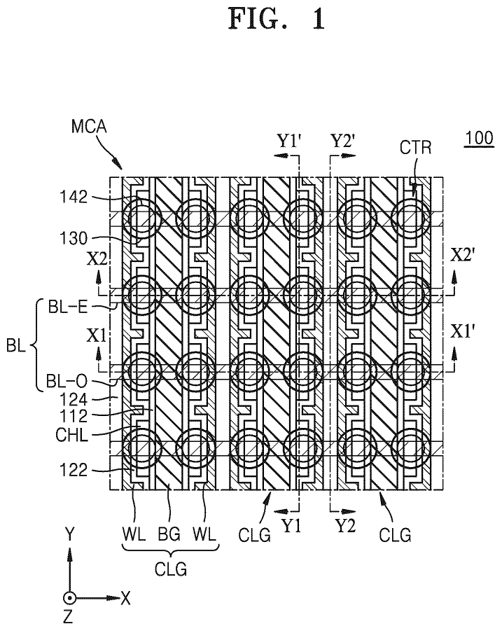

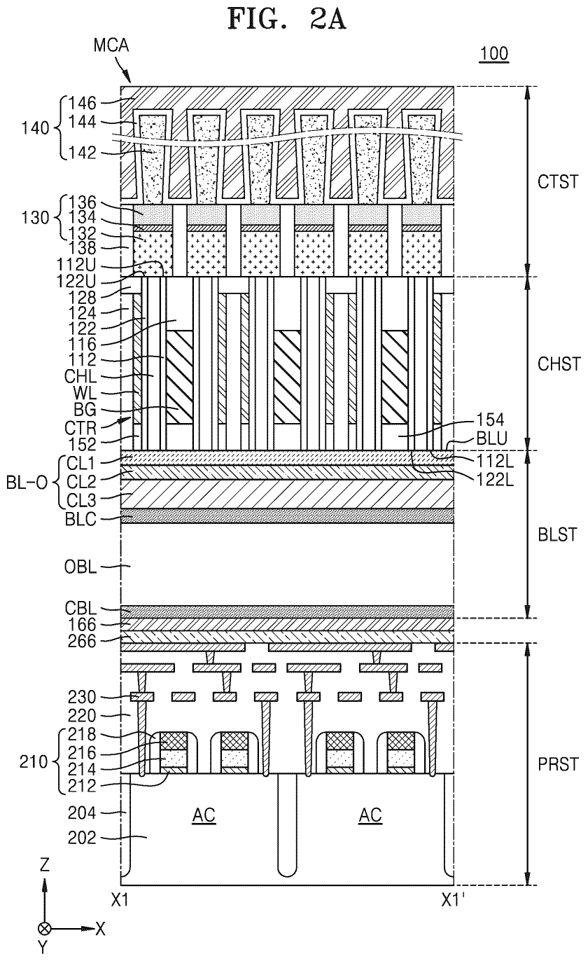

FIG. 1 is a plane layout illustrating a semiconductor memory device according to some example embodiments, and FIGS. 2A to 2D are cross-sectional views of the semiconductor memory device according to some example embodiments. In detail, FIG. 2A is a cross-sectional view taken along line X1-X1′ in FIG. 1, FIG. 2B is a cross-sectional view taken along line X2-X2′ in FIG. 1, FIG. 2C is a cross-sectional view taken along line Y1-Y1′ in FIG. 1, and FIG. 2D is a cross-sectional view taken along line Y2-Y2′ in FIG. 1.

Referring to FIGS. 1 to 2D, a semiconductor memory device 100 may include a memory cell region MCA in which a plurality of memory cells are arranged. For example, the memory cells may include a plurality of vertical channel transistors CTR. The memory cell region MCA may be formed by stacking a bit line structure BLST, a channel structure CHST, and a capacitor structure CTST. In some example embodiment, the semiconductor memory device 100 may have a cell-on-periphery (COP) structure in which the memory cell region MCA overlaps, or at least partially overlaps, a peripheral circuit structure PRST including a peripheral circuit transistor constituted of a circuit gate structure 210 in a vertical direction (a Z direction). For example, the peripheral circuit transistor constituted of or included in or corresponding to the circuit gate structure 210 may be configured to transmit and/or receive a signal and/or power to a plurality of memory cells in the memory cell region MCA. For example, the peripheral circuit transistor constituted by the circuit gate structure 210 may form various kinds of circuits, such as one or more of a command decoder, a control logic, an address buffer, a row decoder, a column decoder, a sense amplifier, and a data input/output circuit. In some example embodiments, the semiconductor memory device 100 may include a peripheral circuit region, which surrounds the memory cell region MCA in a plan view, instead of the peripheral circuit structure PRST. The peripheral circuit region may include a region in which the peripheral circuit transistor constituted of the circuit gate structure 210 is formed.

In some example embodiments, in the semiconductor memory device 100, the bit line structure BLST, the channel structure CHST, and the capacitor structure CTST may be sequentially stacked on the peripheral circuit structure PRST in the vertical direction (the Z direction). The bit line structure BLST may include a plurality of bit lines BL. The channel structure CHST may include a plurality of channel patterns CHL, a plurality of word lines WL, and a plurality of back gate electrodes BG. The capacitor structure CTST may include a plurality of contact plugs 130 and a plurality of capacitors 140. Example embodiments are not limited thereto. For example, in some example embodiments the capacitor structure CTST may include a memristor and/or a hysteresis component in addition to or alternatively to a capacitors 140.

According to some example embodiments, the semiconductor memory device 100 may include a plurality of bit lines BL, which extend lengthwise in a first horizontal direction (an X direction) and are repeatedly arranged spaced apart from each other in a second horizontal direction (a Y direction) perpendicular to the first horizontal direction (the X direction). In some example embodiments, the bit lines BL may be separated from each other by a first interlayer insulating layer OBL in the second horizontal direction (the Y direction). The first interlayer insulating layer OBL may fill all the space between the bit lines BL.

The semiconductor memory device 100 may include a plurality of channel patterns CHL on a plurality of bit lines BL, a plurality of contact plugs 130 respectively on the channel patterns CHL, and a plurality of capacitors 140 in the memory cell region MCA. According to some example embodiments, the channel patterns CHL may be repeatedly arranged on the bit lines BL to be spaced apart from one another in the first horizontal direction (the X direction) and the second horizontal direction (the Y direction). Each of the contact plugs 130 may be on its corresponding one among the channel patterns CHL. Each of the channel patterns CHL may extend in the vertical direction (the Z direction) between a selected one among the bit lines BL and a selected one among the contact plugs 130.

According to some example embodiments, each of the channel patterns CHL may include a first end and a second end opposite to the first end in the vertical direction (the Z direction). In each of the channel patterns CHL, the first end may be connected to one contact plug 130 selected from among the contact plugs 130 and the second end may be connected to one bit line BL selected from among the bit lines BL. In some example embodiments, each channel pattern CHL may include a conductive region, e.g., an impurity-doped well or an impurity-doped structure. Although not shown, an impurity region functioning as a source/drain region may be formed in each of the first end and the second end of the channel pattern CHL.

In some example embodiments, each of the channel patterns CHL may include a semiconductor material. For example, each of the channel patterns CHL may include single-crystalline silicon, polycrystalline silicon, or amorphous silicon. In some example embodiments, each of the channel patterns CHL may include at least one selected from the group consisting of Ge, SiGe, SiC, GaAs, InAs, and InP. In some example embodiments, each of the channel patterns CHL may include an oxide semiconductor material. Each of the channel patterns CHL may include at least one selected from the group consisting of a binary or ternary oxide semiconductor material including a first metal element, a ternary oxide semiconductor material including a first metal element and a second metal element different from the first metal element, and a quaternary oxide semiconductor material including a first metal element, a second metal element, and a third metal element, which are different from one another.

For example, the binary or ternary oxide semiconductor material may include, but not limited to, ZnO (zinc oxide (ZnₓO)), GaO (gallium oxide (GaₓO)), TiO (tin oxide (TiₓO)), ZnON (zinc oxynitride (ZnₓO_{y}N)), IZO (indium zinc oxide (InₓZn_{y}O)), GZO (gallium zinc oxide (GaₓZn_{y}O)), TZO (tin zinc oxide (SnₓZn_{y}O), or TGO (tin gallium oxide (SnₓGa_{y}O)). For example, the quaternary oxide semiconductor material may include, but not limited to, IGZO (indium gallium zinc oxide (InₓGa_{Y}Zn_{z}O)), IGSO (indium gallium silicon oxide (InₓGa_{y}Si_{z}O)), ITZO (indium tin zinc oxide (InₓSn_{Y}Zn_{z}O)), IGTO (indium gallium tin oxide (InₓGa_{y}Sn_{z}O)), ZZTO (zirconium zinc tin oxide (Zr_{X}Zn_{y}Sn_{z}O)), HIZO (hafnium indium zinc oxide (HfₓIn_{Y}Zn_{z}O)), GZTO (gallium zinc tin oxide (Ga_{X}Zn_{y}Sn_{z}O)), AZTO (aluminum zinc tin oxide (Al_{X}Zn_{y}Sn_{z}O)), YGZO (ytterbium gallium zinc oxide (YbₓGa_{Y}Zn_{z}O)), or IAZO (indium aluminum zinc oxide).

In some example embodiments, each of the channel patterns CHL may include a crystalline oxide semiconductor material or an amorphous oxide semiconductor material. When each of the channel patterns CHL includes a crystalline oxide semiconductor material, each channel pattern CHL may have at least one selected from the group consisting of a single crystal, a polycrystal, a spinel, and a c-axis aligned crystal (CAAC). In some example embodiments, each of the channel patterns CHL may be formed by stacking at least two layers, which include a first layer constituted of a crystalline oxide semiconductor material and a second layer constituted of an amorphous oxide semiconductor material. For example, each of the channel patterns CHL may be formed by sequentially stacking a first layer constituted of a crystalline oxide semiconductor material, a second layer constituted of an amorphous oxide semiconductor material, and a third layer constituted of a crystalline oxide semiconductor material.

According to some example embodiments, the contact plugs 130 may be separated from the bit lines BL by the channel patterns CHL in the vertical direction (the Z direction). The contact plugs 130 may be spaced apart from one another in the first horizontal direction (the X direction) and the second horizontal direction (the Y direction) in a matrix. The contact plugs 130 may be respectively connected to the channel patterns CHL.

In some example embodiments, each of the contact plugs 130 may include metal, conductive metal nitride, metal silicide, doped polysilicon, or a combination thereof. For example, each of the contact plugs 130 may include Ti, TiN, Ta, TaN, Mo, Ru, W, WN, Co, Ni, TiSi, TiSiN, WSi, WSiN, TaSi, TaSiN, RuTiN, CoSi, NiSi, doped silicon, or a combination thereof.

In some example embodiments, each of the contact plugs 130 may include a first conductive pattern 132, a second conductive pattern 134, and a third conductive pattern 136, which are sequentially stacked on one of the channel patterns CHL. For example, the first conductive pattern 132 may include doped polysilicon, the second conductive pattern 134 may include metal silicide, and the third conductive pattern 136 may include metal, but embodiments are not limited thereto.

According to some example embodiments, the semiconductor memory device 100 may include a second interlayer insulating layer 138 surrounding the contact plugs 130. In the memory cell region MCA, each of the contact plugs 130 may be in contact with one channel pattern CHL through the second interlayer insulating layer 138. The contact plugs 130 may be separated from each other by the second interlayer insulating layer 138 in a horizontal direction (the X direction and/or the Y direction). In some example embodiments, the second interlayer insulating layer 138 may include silicon oxide, silicon nitride, or a combination thereof.

According to some example embodiments, the semiconductor memory device 100 may include a plurality of back gate electrodes BG and a plurality of word lines WL in the channel structure CHST, wherein the back gate electrodes BG and the word lines WL are arranged on each of the bit lines BL. The back gate electrodes BG and the word lines WL may extend lengthwise in the second horizontal direction (the Y direction) between the bit lines BL and the contact plugs 130. The back gate electrodes BG and the word lines WL may be spaced apart from each other in the first horizontal direction (the X direction). According to some example embodiments, one back gate electrode BG and two word lines WL, which are adjacent to the back gate electrode BG and separated from each other by the back gate electrode BG in the first horizontal direction (the X direction), may form one conductive line group CLG. According to some example embodiments, a plurality of conductive line groups CLG may be separated from each other by an isolation insulating pattern 124 in the first horizontal direction (the X direction) on the bit lines BL. For example, a pair of word lines WL, which are separated by the isolation insulating pattern 124 in the first horizontal direction (the X direction) and respectively included in different conductive line groups CLG, may be arranged between two adjacent back gate electrodes BG.

According to some example embodiments, each of the channel patterns CHL may be arranged on its corresponding bit line BL among the bit lines BL and between one back gate electrode BG and one word line WL, which are adjacent to each other in the first horizontal direction (the X direction) According to some example embodiments, two channel patterns CHL in a pair may be respectively at both sides of each of the plurality of back gate electrodes BG in the first horizontal direction (the X direction), and a pair of word lines WL may be separated from the back gate electrodes BG by a pair of channel patterns CHL.

According to some example embodiments, pairs of channel patterns CHL may be arranged in the second horizontal direction (the Y direction) and cover both sidewalls in the first horizontal direction (the X direction) of one back gate electrode BG in each of the plurality of conductive line groups CLG. For example, each of the pairs of channel patterns CHL may be arranged on its corresponding bit line BL among the bit lines BL, and the pairs of channel patterns CHL may be spaced apart from each other in the second horizontal direction (the Y direction). In each of the conductive line groups CLG, one word line WL among two word lines WL may cover a first group of channel patterns CHL, which cover a first sidewall of a back gate electrode BG among the pairs of channel patterns CHL, and the other word line WL among the two word lines WL may cover a second group of channel patterns CHL, which cover a second sidewall of the back gate electrode BG among the pairs of channel patterns CHL, wherein the second sidewall is opposite to the first sidewall. According to some example embodiments, one side of each of the plurality of channel patterns CHL may face one back gate electrode BG in the first horizontal direction (the X direction), and the opposite side of each of the channel patterns CHL may face one word line WL in the first horizontal direction (the X direction).

In some example embodiments, each of the plurality of back gate electrodes BG may include metal, conductive metal nitride, doped polysilicon, or a combination thereof. For example, each of the back gate electrodes BG may include, but not limited to, Ti, TiN, Ta, TaN, Mo, Ru, W, WN, TiSiN, WSiN, doped polysilicon, or a combination thereof. Each of the plurality of word lines WL may include metal, conductive metal nitride, or a combination thereof. For example, each of the word lines WL may include, but not limited to, Ti, TiN, Ta, TaN, Mo, Ru, W, WN, TiSiN, WSiN, or a combination thereof.

According to some example embodiments, the semiconductor memory device 100 may include a plurality of back gate dielectric films 112 covering both sidewalls of each of the back gate electrodes BG in the first horizontal direction (the X direction) in the channel structure CHST. Each of the back gate dielectric films 112 may be between one back gate electrode BG and one channel pattern CHL adjacent to the back gate electrode BG. For example, each of the back gate dielectric films 112 may be in contact with the back gate electrode BG and the channel pattern CHL. Each of the back gate dielectric films 112 may include an end in contact with the bit lines BL and an opposite end in contact with some of the contact plugs 130 in the vertical direction (the Z direction). For example, each of the back gate dielectric films 112 may have a first surface 112U and a second surface 112L opposite to the first surface 112U in the vertical direction (the Z direction). The first surface 112U of each of the back gate dielectric films 112 may face some of the contact plugs 130, and the second surface 112L of each of the back gate dielectric films 112 may face the bit lines BL. For example, the first surface 112U of each of the back gate dielectric films 112 may include a portion in contact with first conductive patterns 132 of some of the contact plugs 130. For example, the second surface 112L of each of the back gate dielectric films 112 may be in contact with the bit lines BL.

According to some example embodiments, a first capping insulating pattern 116 may be between two adjacent channel patterns CHL and between a back gate electrode BG and a plurality of contact plugs 130. A second capping insulating pattern 154 may be between the two adjacent channel patterns CHL and between the back gate electrode BG and a bit line BL. In some example embodiments, the first capping insulating pattern 116, the back gate electrode BG, and the second capping insulating pattern 154 may overlap one another in the vertical direction (the Z direction), and each of both sidewalls in the first horizontal direction (the X direction) of each of the first capping insulating pattern 116, the back gate electrode BG, and the second capping insulating pattern 154 may be in contact with and covered with a back gate dielectric film 112. The back gate electrode BG may be separated from the contact plugs 130 by the first capping insulating pattern 116 in the vertical direction (the Z direction). The back gate electrode BG may be separated from the bit lines BL by the second capping insulating pattern 154 in the vertical direction (the Z direction). In some example embodiments, each of the first capping insulating pattern 116 and the second capping insulating pattern 154 may include silicon oxide, silicon nitride, or a combination thereof.

According to some example embodiments, the semiconductor memory device 100 may include a plurality of gate dielectric films 122 in the channel structure CHST, wherein each of the gate dielectric films 122 is between a word line WL and a channel pattern CHL adjacent to the word line WL. A pair of gate dielectric films 122 may be between two channel patterns CHL, which are separated from each other with the isolation insulating pattern 124 therebetween and adjacent to each other in the first horizontal direction (the X direction). A pair of word lines WL may be between the gate dielectric films 122 in the pair. Each of the gate dielectric films 122 in the pair may be between one word line WL and channel patterns CHL, which are adjacent to the word line WL and arranged in the second horizontal direction (the Y direction), among the plurality of channel patterns CHL and may be in contact with the word line WL and the channel patterns CHL. Each of the gate dielectric films 122 in the pair may include an end in contact with the bit lines BL and an opposite end in contact with some of the contact plugs 130. For example, each of the gate dielectric films 122 may have a first surface 122U and a second surface 122L opposite to the first surface 122U in the vertical direction (the Z direction). The first surface 122U of each of the gate dielectric films 122 may face some of the contact plugs 130, and the second surface 122L of each of the gate dielectric films 122 may face the bit lines BL. For example, the first surface 122U of each of the gate dielectric films 122 may include a portion in contact with the first conductive patterns 132 of some of the contact plugs 130. For example, the second surface 122L of each of the gate dielectric films 122 may be in contact with the bit lines BL.

According to some example embodiments, a sidewall of each of the channel patterns CHL in the first horizontal direction (the X direction) may be in contact with one of the back gate dielectric films 112 and an opposite sidewall of each of the channel patterns CHL in the first horizontal direction (the X direction) may be in contact with one of the gate dielectric films 122. According to some example embodiments, both sidewalls of each of the channel patterns CHL in the second horizontal direction (the Y direction) may be in contact with its corresponding gate dielectric film 122 among the gate dielectric films 122 and may face its corresponding word line WL among the plurality of word lines WL with the gate dielectric film 122 between the both sidewalls of each channel pattern CHL.

According to some example embodiments, the isolation insulating pattern 124 may be between two word lines WL between two adjacent channel patterns CHL. A first buried insulating pattern 128 may be between a pair of word lines WL and a plurality of contact plugs 130, and a pair of second buried insulating patterns 152 may be between the pair of word lines WL and a bit line BL. The pair of second buried insulating patterns 152 may be separated from each other by the isolation insulating pattern 124 in the first horizontal direction (the X direction). The pair of word lines WL, the first buried insulating pattern 128, and the pair of second buried insulating patterns 152 may overlap one another in the vertical direction (the Z direction) between two adjacent of channel patterns CHL. The pair of word lines WL may be separated from the contact plugs 130 by the first buried insulating pattern 128 in the vertical direction (the Z direction). The pair of word lines WL may be separated from the plurality of bit lines BL by the pair of second buried insulating patterns 152. In some example embodiments, each of the isolation insulating pattern 124, the first buried insulating pattern 128, and the second buried insulating patterns 152 may include silicon oxide, silicon nitride, or a combination thereof.

According to some example embodiments, the gate dielectric films 122 and the back gate dielectric films 112 may each include a silicon oxide film, a high-k film, or a combination thereof. The term “high-k film” used herein may refer to a dielectric film having a higher dielectric constant than silicon oxide. In embodiments, the gate dielectric films 122 and the back gate dielectric films 112 may each include at least one material selected from the group consisting of silicon oxide, hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO). The plurality of back gate electrodes BG, the plurality of word lines WL, the plurality of channel patterns CHL, the plurality of back gate dielectric films 112, and the plurality of gate dielectric films 122 may be between the plurality of bit lines BL and the plurality of contact plugs 130 and may form the plurality of vertical channel transistors CTR. Here, the vertical channel transistors CTR may be referred to as a vertical channel transistor structure.

The channel patterns CHL, the word lines WL, the back gate electrodes BG, the back gate dielectric films 112, and the gate dielectric films 122 may form the channel structure CHST. The channel structure CHST may further include various insulating patterns, such as a plurality of first capping insulating patterns 116, a plurality of isolation insulating patterns 124, a plurality of first buried insulating patterns 128, a plurality of second buried insulating patterns 152, and a plurality of second capping insulating patterns 154.

Although it is illustrated in FIGS. 2A and 2B that the top surfaces of the back gate electrodes BG are closer to the bit lines BL than the top surfaces of the word lines WL, the inventive concept is not limited thereto. For example, the top surfaces of the back gate electrodes BG may be at the same vertical level as the top surface of the word lines WL or may be closer to the contact plugs 130 than the top surfaces of the word lines WL. Here, the “vertical level” refers to a distance from a first surface BLU of each of the bit lines BL, which faces the contact plugs 130, in a Z direction and/or −Z direction.

The capacitors 140 may be arranged on the contact plugs 130 and the second interlayer insulating layer 138. The capacitors 140 may include a plurality of lower electrodes 142 respectively connected to the contact plugs 130, a capacitor dielectric film 144 conformally covering the surfaces of the lower electrode 142, and an upper electrode 146 covering the lower electrodes 142 with the capacitor dielectric film 144 between the upper electrode 146 and the lower electrodes 142. Each of the lower electrodes 142 may be connected to a channel pattern CHL through one contact plug 130 selected from among the contact plugs 130. The third conductive pattern 136 of each of the contact plugs 130 may function as a landing pad with which one lower electrode 142 selected from among the lower electrodes 142 is in contact.

Each of the lower electrodes 142 may have, but not limited to, a solid pillar shape having a circular horizontal cross-section. In some example embodiments, each of the lower electrodes 142 may have a cylindrical shape with a closed bottom. In some example embodiments, the lower electrodes 142 may be arranged in lines in the first horizontal direction (the X direction) and the second horizontal direction (the Y direction) in a matrix pattern. In some example embodiments, the lower electrodes 142 may be arranged to zigzag in the first horizontal direction (the X direction) or the second horizontal direction (the Y direction) in a honeycomb pattern. The lower electrodes 142 may include, for example, impurity-doped silicon, a metal such as tungsten or copper, or a conductive metal compound such as titanium nitride.

The capacitor dielectric film 144 may conformally cover the surfaces of the lower electrodes 142. In some example embodiments, the capacitor dielectric film 144 may include a high-k film. In some example embodiments, the capacitor dielectric film 144 may include metal oxide including at least one metal selected from the group consisting of hafnium (Hf), zirconium (Zr), aluminum (Al), niobium (Nb), cerium (Ce), lanthanum (La), tantalum (Ta), and titanium (Ti). In some example embodiments, the lower electrodes 142 and the upper electrode 146 may each include metal, conductive metal oxide, conductive metal nitride, conductive metal oxynitride, or a combination thereof. In some example embodiments, the lower electrodes 142 and the upper electrode 146 may each include Nb, Nb oxide, Nb nitride, Nb oxynitride, Ti, Ti oxide, Ti nitride, Ti oxynitride, Co, Co oxide, Co nitride, Co oxynitride, Sn, Sn oxide, Sn nitride, Sn oxynitride, or a combination thereof. In some example embodiments, the lower electrodes 142 and the upper electrode 146 may each include TaN, TiAlN, TaAlN, V, VN, Mo, MoN, W, WN, Ru, RuO₂, SrRuO₃, Ir, IrO₂, Pt, PtO, SRO(SrRuO₃), BSRO((Ba,Sr)RuO₃), CRO(CaRuO₃), LSCO((La,Sr)CoO₃), or a combination thereof. However, the material of each of the lower electrodes 142 and the upper electrode 146 is not limited to those mentioned above. In some example embodiments, the upper electrode 146 may further include at least one of a doped semiconductor material layer and an interface layer in addition to the metal material and may have a stack structure thereof. For example, the doped semiconductor material layer may include at least one of doped polysilicon and doped polycrystalline silicon germanium (SiGe). For example, the interface layer may include at least one selected from the group consisting of metal oxide, metal nitride, metal carbide, and metal silicide. The contact plugs 130, the second interlayer insulating layer 138, and the capacitors 140 may form the capacitor structure CTST.

In a plan view, the bit lines BL may include a plurality of first bit lines BL-O and a plurality of second bit lines BL-E. The first bit lines BL-O may be separately and alternately arranged with the second bit lines BL-E in the second horizontal direction (the Y direction).

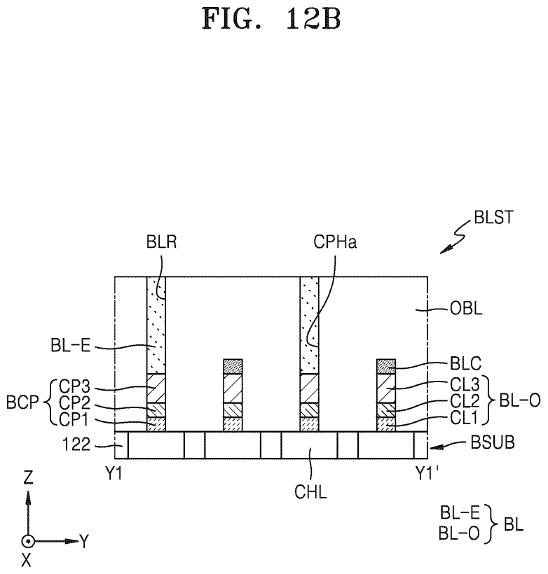

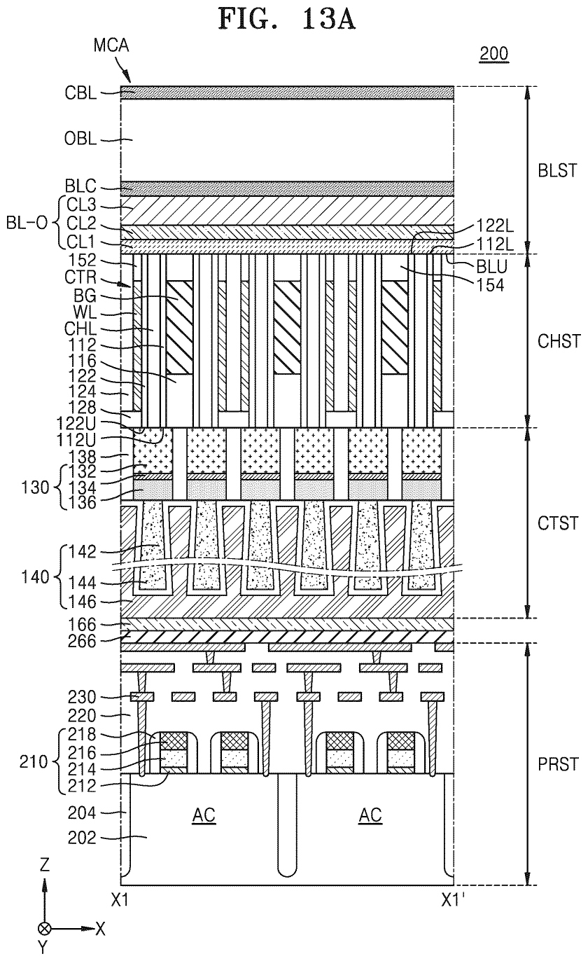

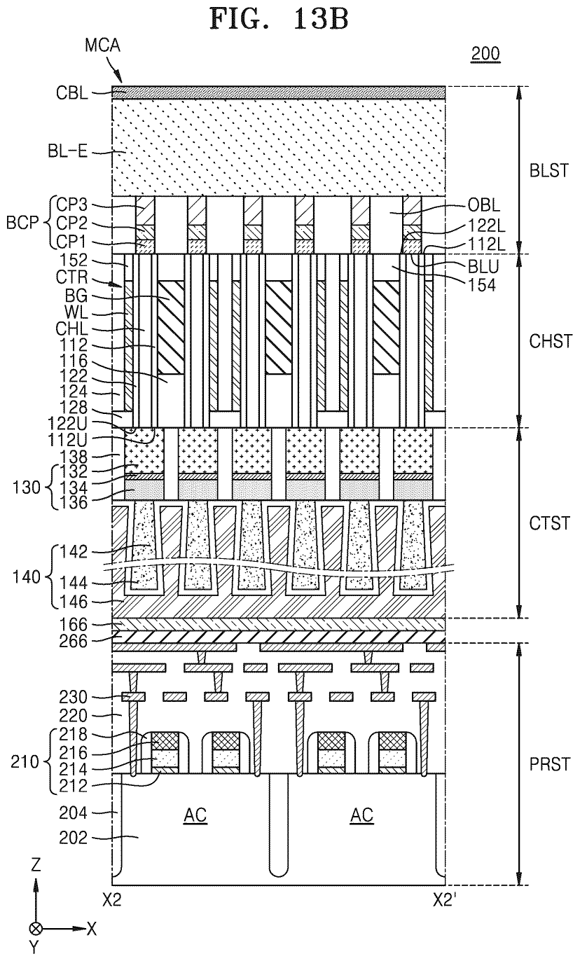

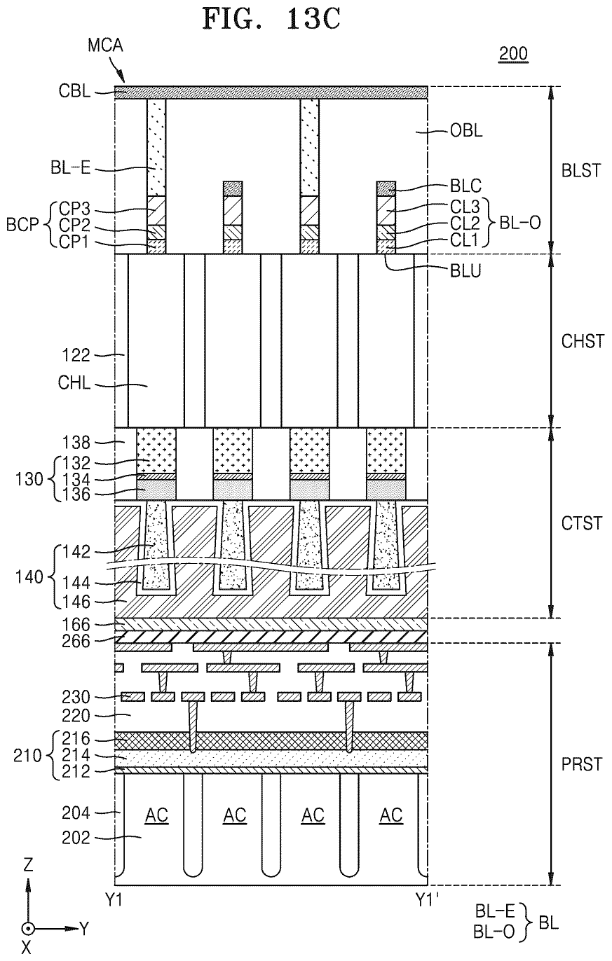

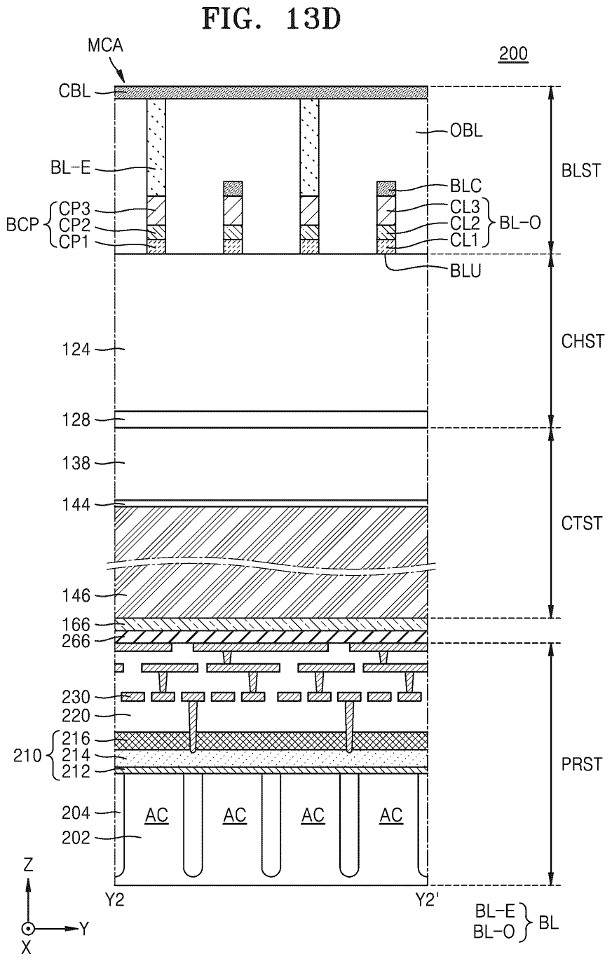

Each of the first bit lines BL-O may have a stack structure of a first line pattern CL1, a second line pattern CL2, and a third line pattern CL3. For example, the first line pattern CL1 may include a semiconductor material, and each of the second line pattern CL2 and the third line pattern CL3 may include a metal-based material. The second line pattern CL2 and the third line pattern CL3 may include different metal-based materials from each other. For example, the first line pattern CL1 may include doped polysilicon. For example, the second line pattern CL2 may include titanium nitride (TiN) or Ti—Si—N (TSN). The third line pattern CL3 may include tungsten (W) or tungsten (W) and tungsten silicide (WSiₓ). In some example embodiments, the second line pattern CL2 may function as a diffusion barrier. An insulating capping line BLC may be disposed on the third line pattern CL3. The first line pattern CL1, the second line pattern CL2, the third line pattern CL3, and the insulating capping line BLC may be sequentially arranged on the channel patterns CHL. Although it is illustrated in FIGS. 2A, 2C, and 2D that the first line pattern CL1, the second line pattern CL2, the third line pattern CL3, and the insulating capping line BLC are sequentially arranged below the second ends of the channel patterns CHL, embodiments are not limited thereto. For example, as shown in FIGS. 13A, 13C, and 13D, the first line pattern CL1, the second line pattern CL2, the third line pattern CL3, and the insulating capping line BLC may be sequentially arranged above the second ends of the channel patterns CHL.

The second bit lines BL-E may be disposed on a plurality of bit line contacts BCP. Each of the second bit lines BL-E may include a metal-based material. For example, the second bit lines BL-E may include tungsten (W) or tungsten (W) and tungsten silicide (WSiₓ). Each of the bit line contacts BCP may have a stack structure of a first contact pattern CP1, a second contact pattern CP2, and a third contact pattern CP3. A second bit line BL-E may be disposed on the third contact pattern CP3. For example, the first contact pattern CP1 may include a semiconductor material, and each of the second contact pattern CP2 and the third contact pattern CP3 may include a metal-based material. The second contact pattern CP2 and the third contact pattern CP3 may include different metal-based materials from each other. The first contact pattern CP1 may include the same material as the first line pattern CL1. The second contact pattern CP2 may include the same material as the second line pattern CL2. The third contact pattern CP3 may include the same material as the third line pattern CL3. The first contact pattern CP1, the second contact pattern CP2, the third contact pattern CP3, and the second bit line BL-E may be sequentially arranged on a channel pattern CHL. Each of the bit line contacts BCP may be at the same vertical level as at least a portion of s first bit line BL-O. For example, the first line pattern CL1 may be at the same vertical level as the first contact pattern CP1, the second line pattern CL2 may be at the same vertical level as the second contact pattern CP2, and at least a portion of the third line pattern CL3 may be at the same vertical level as the third contact pattern CP3. The third line pattern CL3 may be in contact with the insulating capping line BLC and may be between the insulating capping line BLC and the second line pattern CL2. The third contact pattern CP may be in contact with the second bit line BL-E and may be between the second bit line BL-E and the second contact pattern CP2.

Although it is illustrated in FIGS. 2B, 2C, and 2D that the first contact pattern CP1, the second contact pattern CP2, the third contact pattern CP3, and the second bit line BL-E are sequentially arranged below the second end of the channel pattern CHL, embodiments are not limited thereto. For example, as shown in FIGS. 13B, 13C, and 13D, the first contact pattern CP1, the second contact pattern CP2, the third contact pattern CP3, and the second bit line BL-E may be sequentially arranged above the second end of the channel pattern CHL.

The bit line contacts BCP may be repeatedly arranged spaced apart from each other in the first horizontal direction (the X direction) and the second horizontal direction (the Y direction) on the plurality of second bit lines BL-E. The bit line contacts BCP may form a plurality of lines in the first horizontal direction (the X direction) between a plurality of first bit lines BL-O. Each of the second bit lines BL-E may be connected to channel patterns CHL in a line in the first horizontal direction (the X direction) among the plurality of channel patterns CHL through the bit line contacts BCP in one line in the first horizontal direction (the X direction) among the plurality of bit line contacts BCP.

The first line pattern CL1 and the first contact pattern CP1 may be alternately connected to the channel patterns CHL in a line in the second horizontal direction (the Y direction). In other words, the first bit lines BL-O and the second bit lines BL-E may be alternately connected to the channel pattern CHL in a line in the second horizontal direction (the Y direction). The first interlayer insulating layer OBL may surround the first bit lines BL-O, a plurality of insulating capping lines BLC, the bit line contacts BCP, and the second bit lines BL-E. A capping line CBL may be disposed on the first interlayer insulating layer OBL and the second bit lines BL-E. For example, the capping line CBL may cover the bottom surfaces of the first interlayer insulating layer OBL and the second bit lines BL-E. The first interlayer insulating layer OBL may include silicon oxide, silicon nitride, or a combination thereof. In some example embodiments, the first interlayer insulating layer OBL may include silicon oxide, silicon nitride, or a combination thereof. For example, each of the insulating capping lines BLC and the capping line CBL may include silicon nitride.

For example, the first bit lines BL-O, the insulating capping lines BLC, the bit line contacts BCP, the second bit lines BL-E, the first interlayer insulating layer OBL, and the capping line CBL may form the bit line structure BLST.

At least a portion of each of the first bit lines BL-O may be at a different vertical level than the second bit lines BL-E, and at least a portion of each of the second bit lines BL-E may be at a different vertical level than the first bit lines BL-O. Although it is illustrated in FIGS. 2A to 2D that a lower portion of the third line pattern CL3 of each of the first bit lines BL-O is at the same vertical level as an upper portion of each of the second bit lines BL-E and the remaining portion of each of the first bit lines BL-O is at a different vertical level than the remaining portion of each of the second bit lines BL-E, embodiments are not limited thereto. In some example embodiments, the first bit lines BL-O may be at a different vertical level than the second bit lines BL-E. For example, the bottom surface of the third line pattern CL3 of each of the first bit lines BL-O may be at the same vertical level as the top surface of each of the second bit lines BL-E.

In some example embodiments, a first bonding insulating layer 166 may be disposed on the capping line CBL. For example, the first bonding insulating layer 166 may cover the bottom surface of the capping line CBL. For example, the first bonding insulating layer 166 may include silicon oxide or silicon carbonitride (SiCN).

The peripheral circuit structure PRST may include a circuit substrate 202 having a plurality of active regions AC defined by a circuit device isolation film 204, a plurality of circuit gate structures 210 arranged in the active regions AC of the circuit substrate 202, an inter-wiring insulating layer 220 on the circuit substrate 202 and covering the circuit gate structures 210, and a wiring structure 230 surrounded by the inter-wiring insulating layer 220 and electrically connected to the active regions AC and/or the circuit gate structures 210. A second bonding insulating layer 266 may be disposed on the peripheral circuit structure PRST. For example, the second bonding insulating layer 266 may cover the inter-wiring insulating layer 220 and the wiring structure 230.

A number of layers included in the peripheral circuit structure PRST and/or an orientation of the circuit gate structures 210 are not limited to features described in FIGS. 2A-2D. For example, there may be more or fewer layers, and/or there may transistors oriented in the same and/or in different directions, and/or there may be three-dimensional transistors in addition to or alternatively from the planar transistors illustrated in FIGS. 2A-2D.

The circuit substrate 202 may include a semiconductor material, such as one or more of a Group IV semiconductor material, a Group III-V semiconductor material, a Group II-VI semiconductor material, or a Group II-VI oxide semiconductor material. For example, the Group IV semiconductor material may include one or more of silicon (Si), germanium (Ge), or silicon-germanium (Si—Ge). For example, the Group III-V semiconductor material may include gallium arsenide (GaAs), indium phosphide (InP), gallium phosphide (GaP), indium arsenide (InAs), indium antimonide (InSb), or indium gallium arsenide (InGaAs). For example, the Group II-VI semiconductor material may include zinc telluride (ZnTe) or cadmium sulfide (CdS). The circuit substrate 202 may include a bulk wafer or an epitaxial layer. The circuit substrate 202 may be provided as a bulk wafer or bulk layer, and/or an epitaxial layer. In some example embodiments, the circuit substrate 202 may include a silicon-on-insulator (SOI) substrate and/or a germanium-on-insulator (GeOI) substrate. The active regions AC may be defined in the circuit substrate 202 by the circuit device isolation film 204. An active region AC and a circuit gate structure 210 may form a peripheral circuit transistor.

The circuit gate structure 210 may include a circuit gate electrode 214 on the active region AC, a circuit gate insulating layer 212 between the active region AC and the circuit gate electrode 214, a circuit gate capping layer 216 covering the circuit gate electrode 214, and a circuit gate spacer 218 covering the side surfaces of the circuit gate insulating layer 212, the circuit gate electrode 214, and the circuit gate capping layer 216.

The wiring structure 230 may include a circuit wiring line and a circuit wiring contact. The wiring structure 230 may include a conductive material, such as copper (Cu), aluminum (Al), tungsten (W), silver (Ag), gold (Au), or a combination thereof. The inter-wiring insulating layer 220 may include an insulating material including silicon oxide, silicon nitride, a low-k material, or a combination thereof. The low-k material may have a lower dielectric constant than silicon oxide and may include, for example, phosphosilicate glass (PSG), borophosphosilicate glass (BPSG), fluorosilicate glass (FSG), organosilicate glass (OSG), spin-on-glass (SOG), spin-on-polymer, or a combination thereof. In some example embodiments, the inter-wiring insulating layer 220 may include an ultra low-k (ULK) film having an ultra-low dielectric constant K of about 2.2 to about 2.4. The ULK film may include SiOC or SiCOH.

The second bonding insulating layer 266 may include silicon oxide and/or silicon carbonitride (SiCN). The second bonding insulating layer 266 may be covalently bonded to the first bonding insulating layer 166. The bit line structure BLST of the memory cell region MCA may be bonded to the peripheral circuit structure PRST by a hybrid bonding method.

According to some example embodiments, because at least a portion of each of the first bit lines BL-O and at least a portion of each of the second bit lines BL-E are at different vertical levels in the semiconductor memory device 100, interference may not occur or may be reduced in occurrence between the bit lines BL, and the degree of freedom of the critical dimension (CD) of the bit lines may be increased. Accordingly, a shield conductive layer filling the space between the bit lines BL may not be necessary and/or may not be present, which may decrease parasitic capacitance occurring in the bit line structure BLST. As a result, the operational reliability of the semiconductor memory device 100 may be increased.

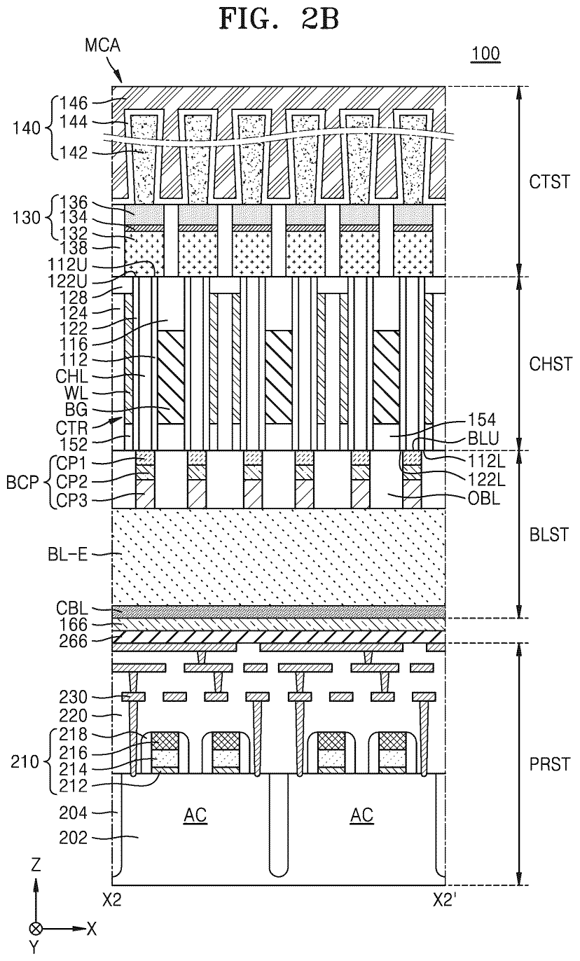

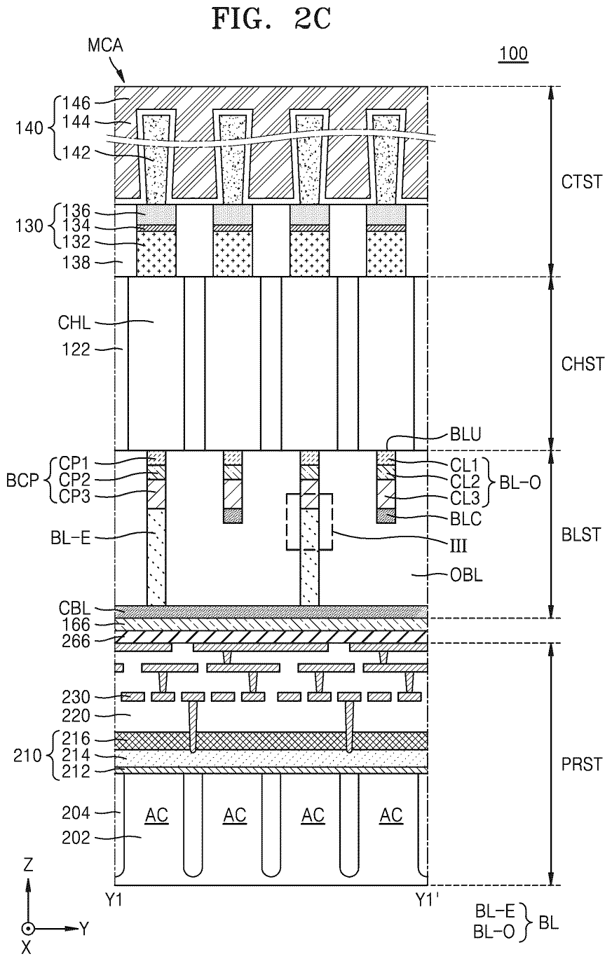

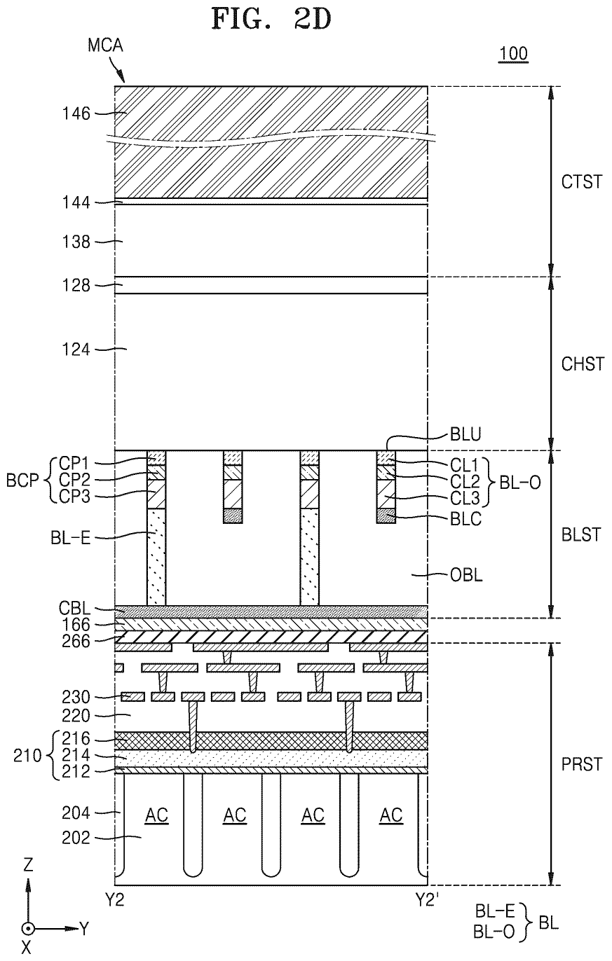

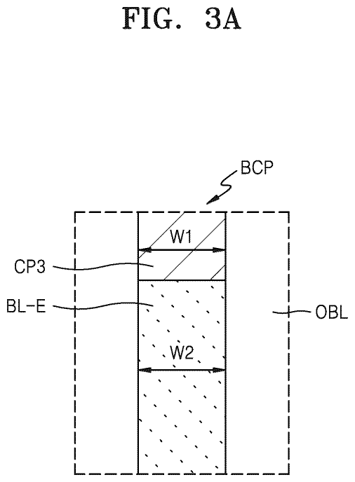

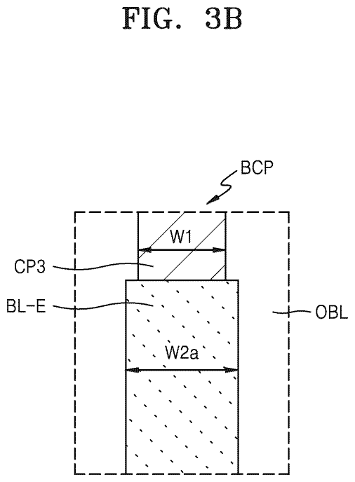

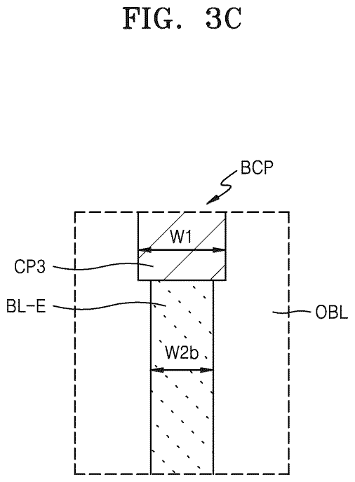

FIGS. 3A to 3C are enlarged views of a region III in FIG. 2C.

Referring to FIG. 3A, the first interlayer insulating layer OBL may surround a bit line contact BCP and a second bit line BL-E. The third contact pattern CP3 of the bit line contact BCP may be connected to the second bit line BL-E. In the second horizontal direction (the Y direction), a first horizontal width W1 of the third contact pattern CP3 may have the same value as a second horizontal width W2 of the second bit line BL-E. In some example embodiments, the first horizontal width W1 may correspond to the horizontal width of the bit line contact BCP in the second horizontal direction (the Y direction). In some example embodiments, the first horizontal width W1 may correspond to the horizontal width of the first bit line BL-O in FIGS. 2C and 2D in the second horizontal direction (the Y direction). In some example embodiments, a sidewall of the second bit line BL-E may be coplanar with a sidewall of the third contact pattern CP3; example embodiments are not limited thereto.

Referring to FIG. 3B, the first interlayer insulating layer OBL may surround a bit line contact BCP and a second bit line BL-E. The third contact pattern CP3 of the bit line contact BCP may be connected to the second bit line BL-E. In the second horizontal direction (the Y direction), the first horizontal width W1 of the third contact pattern CP3 and a second horizontal width W2a of the second bit line BL-E may have different values. For example, the first horizontal width W1 may have a smaller value than the second horizontal width W2a.

Referring to FIG. 3C, the first interlayer insulating layer OBL may surround a bit line contact BCP and a second bit line BL-E. The third contact pattern CP3 of the bit line contact BCP may be connected to the second bit line BL-E. In the second horizontal direction (the Y direction), the first horizontal width W1 of the third contact pattern CP3 and a second horizontal width W2b of the second bit line BL-E may have different values. For example, the first horizontal width W1 may have a greater value than the second horizontal width W2b.

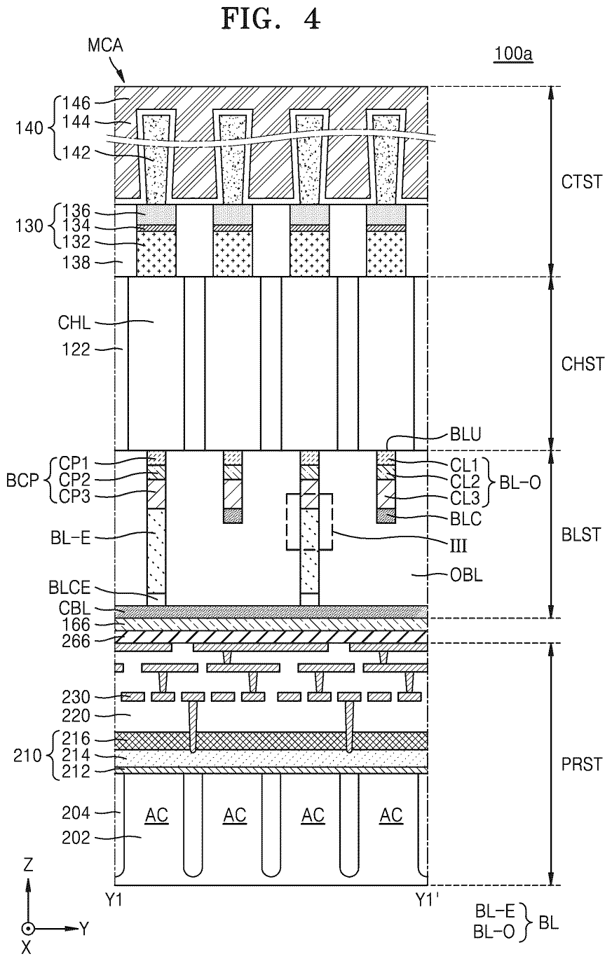

FIG. 4 is a cross-sectional view of a semiconductor memory device according to some example embodiments. In detail, FIG. 4 is a cross-sectional view taken along line Y1-Y1′ in FIG. 1.

Referring to FIG. 4, a semiconductor memory device 100a may include a memory cell region MCA, which is formed by stacking a bit line structure BLST, a channel structure CHST, and a capacitor structure CTST, and a peripheral circuit structure PRST.

Unlike the bit line structure BLST of the semiconductor memory device 100 of FIGS. 2A to 2D, the bit line structure BLST of the semiconductor memory device 100a of FIG. 4 may further include a plurality of cover capping lines BLCE. A cover capping line BLCE may be disposed on a second bit line BL-E. An insulating capping line BLC may be referred to as a first capping line, and the cover capping line BLCE may be referred to as a second capping line.

The plurality of cover capping lines BLCE may be between a plurality of second bit lines BL-E and a capping layer CBL. In some example embodiments, the capping layer CBL may be omitted. Although it is illustrated in FIG. 4 that the cover capping line BLCE is below the second bit line BL-E, example embodiments are not limited thereto. For example, the cover capping line BLCE may be above the second bit line BL-E, as shown in FIGS. 13B, 13C, and 13D.

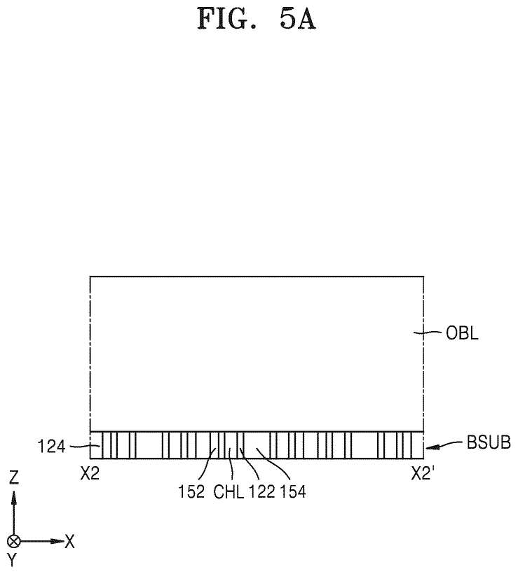

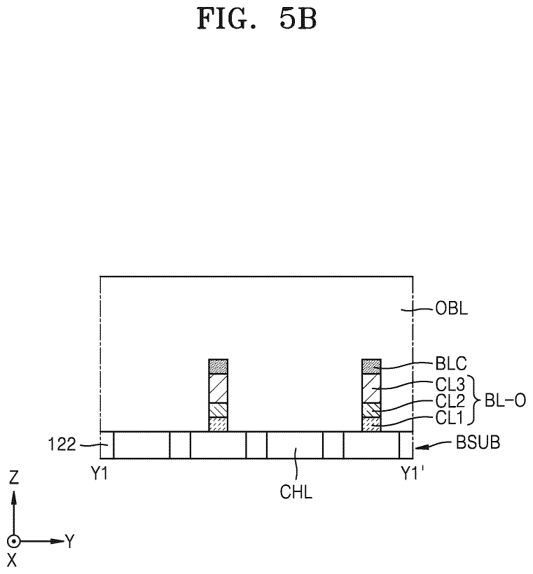

FIGS. 5A to 8B are cross-sectional views illustrating a method of manufacturing a bit line structure included in a semiconductor memory device, according to some example embodiments. In detail, FIGS. 5A, 6A, 7A, and 8A are respectively cross-sectional views illustrating a section cut along a portion corresponding to line X2-X2′ in FIG. 1, and FIGS. 5B, 6B, 7B, and 8B are respectively cross-sectional views illustrating a section cut along a portion corresponding to line Y1-Y1′ in FIG. 1.

Referring to FIGS. 5A and 5B, a plurality of first bit lines BL-O, a plurality of insulating capping lines BLC respectively covering the first bit lines BL-O, and a first interlayer insulating layer OBL surrounding the first bit lines BL-O and the insulating capping lines BLC may be formed on a base substrate structure BSUB. Each of the first bit lines BL-O may have a stack structure of a first line pattern CL1, a second line pattern CL2, and a third line pattern CL3. The insulating capping lines BLC may respectively cover a plurality of third line patterns CL3.

In some example embodiments, the base substrate structure BSUB may correspond to the channel structure CHST in FIGS. 2A to 2D and FIG. 4. For example, the first bit lines BL-O may be alternately connected to channel patterns CHL arranged in the second horizontal direction (the Y direction). A channel pattern CHL that is not connected to any one of the first bit lines BL-O may be between two channel patterns CHL respectively connected to two first bit lines BL-O adjacent to each other in the second horizontal direction (the Y direction) among the first bit lines BL-O.

In some example embodiments, the base substrate structure BSUB may correspond to a base substrate in which a channel structure CHST is not formed. The base substrate may correspond to a semiconductor substrate including a semiconductor material. For example, the base substrate may correspond to a semiconductor substrate including a semiconductor element, such as at least one of silicon (Si) or germanium (Ge), or at least one compound semiconductor selected from the group consisting of or the group including silicon germanium (SiGe), silicon carbide (SiC), gallium arsenide (GaAs), indium arsenide (InAs), and indium phosphide (InP). The base substrate may be removed before the channel structure CHST is formed, and the channel structure CHST may be formed in a space from which the base substrate has been removed.

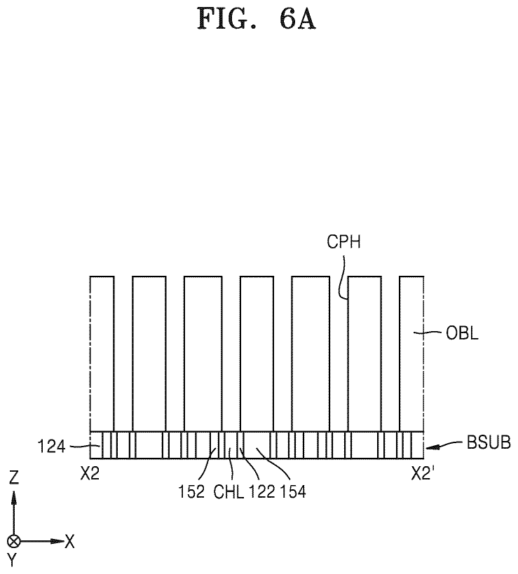

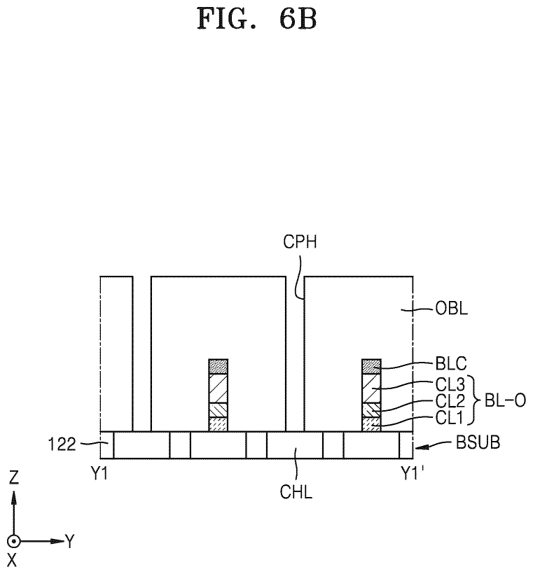

Referring to FIGS. 6A and 6B, a plurality of contact holes CPH may be formed through the first interlayer insulating layer OBL, e.g., with an etch such as an anisotropic etch. The base substrate structure BSUB may be exposed at the bottoms of the contact holes CPH. For example, when the base substrate structure BSUB corresponds to the channel structure CHST in FIGS. 2A to 2D and FIG. 4, channel patterns CHL that are not connected to any one of the first bit lines BL-O may be exposed at the bottoms of the contact holes CPH. The contact holes CPH may be repeatedly arranged spaced apart from one another in the first horizontal direction (the X direction) and the second horizontal direction (the Y direction).

Referring to FIGS. 7A and 7B, a plurality of bit line contacts BCP respectively filling lower portions of the contact holes CPH may be formed. Each of the bit line contacts BCP may have a stack structure of a first contact pattern CP1, a second contact pattern CP2, and a third contact pattern CP3. In some example embodiments, the top surface of the third contact pattern CP3 may be at the same vertical level as the top surface of the third line pattern CL3.

After the bit line contacts BCP are formed, a plurality of bit line recesses BLR may be formed. The bit line recesses BLR may extend downwards from the top surface of the first interlayer insulating layer OBL. The bit line contacts BCP, e.g., a plurality of third contact patterns CP3, may be exposed at the bottoms of the bit line recesses BLR. The bit line recesses BLR may extend lengthwise in the first horizontal direction (the X direction) and may be repeatedly arranged spaced apart from each other in the second horizontal direction (the Y direction). Each of the bit line recesses BLR may be formed such that among portions of the contact holes CPH which are not filled with the bit line contacts BCP, the portions of contact holes CPH arranged in a line in the first horizontal direction (the X direction) communicate with each other. The first interlayer insulating layer OBL and the top surfaces of the bit line contacts BCP arranged in line in the first horizontal direction (the X direction) may be exposed at the bottoms of the bit line recesses BLR.

In some example embodiments, upper portions of the third contact patterns CP3 may be removed in a process of forming the bit line recesses BLR such that the top surface of each of the third contact patterns CP3 may be at a lower vertical level than the top surface of each of a plurality of third line patterns CL3. However, example embodiments are not limited thereto. For example, the third contact patterns CP3 may not be removed in the process of forming the bit line recesses BLR such that the top surface of each of the third contact patterns CP3 may be at the same vertical level as the top surface of each the third line patterns CL3.

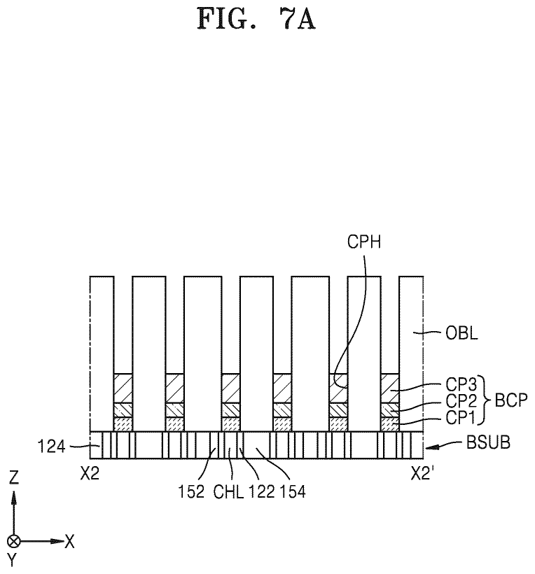

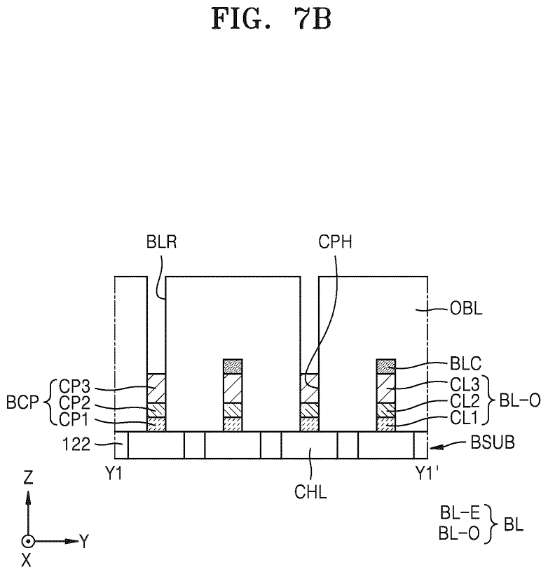

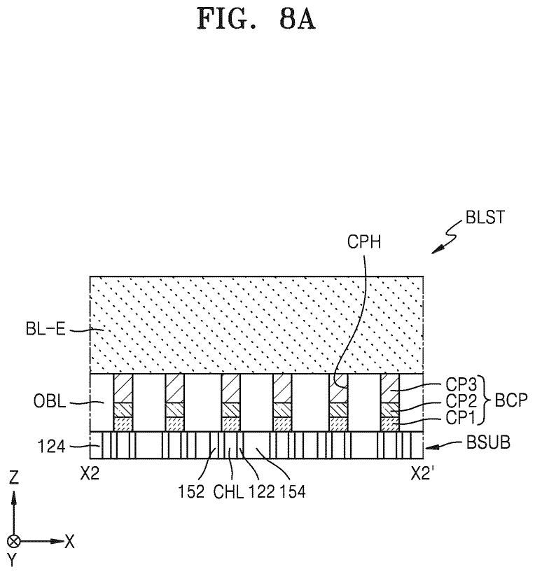

Referring to FIGS. 8A and 8B, a bit line structure BLST may be formed by forming a plurality of second bit lines BL-E filling the bit line recesses BLR, e.g., with a deposition process such at least one of a physical deposition process, a chemical vapor deposition (CVD) process, or an atomic layer deposition (ALD) process, such as at least one of a plasma enhanced CVD process, a low pressure CVD, process, or a physical deposition process. The second bit lines BL-E may extend lengthwise in the first horizontal direction (the X direction) and may be repeatedly arranged spaced apart from each other in the second horizontal direction (the Y direction). The second bit lines BL-E may be respectively formed on the bit line contacts BCP. Each of the second bit lines BL-E may be in contact with bit line contacts BCP arranged in a line in the first horizontal direction (the X direction) among the plurality of bit line contacts BCP. For example, the bottom surface of each of the second bit lines BL-E may be covered with the first interlayer insulating layer OBL and the top surfaces of bit line contacts BCP arranged in a line in the first horizontal direction (the X direction) among the plurality of bit line contacts BCP.

The second bit lines BL-E may be formed by forming a conductive material layer, which fills the bit line recesses BLR and covers the first interlayer insulating layer OBL, and removing a portion of the conductive material layer covering the top surface of the first interlayer insulating layer OBL. In some example embodiments, in the process of removing the portion of the conductive material layer covering the top surface of the first interlayer insulating layer OBL, a portion of the conductive material layer filling upper portions of the bit line recesses BLR may be further removed. Thereafter, the cover capping lines BLCE in FIG. 4 may be formed by filling the upper portions of the bit line recesses BLR, from which the other portion of the conductive material layer is removed, with an insulating material.

In some example embodiments, after the second bit lines BL-E are formed, the capping layer CBL shown in FIGS. 2A to 2D may be formed.

Thereafter, as shown in FIGS. 2A to 2D or FIG. 4, after the first bonding insulating layer 166 is formed, the bit line structure BLST may be bonded to the peripheral circuit structure PRST on which the second bonding insulating layer 266 is formed, and the capacitor structure CTST may be formed on the channel structure CHST. Accordingly, the semiconductor memory device 100 of FIGS. 2A to 2D or the semiconductor memory device 100a of FIG. 4 may be formed. In some example embodiments, when the base substrate structure BSUB corresponds to a base substrate without the channel structure CHST, the first bonding insulating layer 166 may be formed as shown in FIGS. 2A to 2D or FIG. 4, and then, the bit line structure BLST may be bonded to the peripheral circuit structure PRST on which the second bonding insulating layer 266 is formed, the base substrate may be removed, and the channel structure CHST and the capacitor structure CTST may be formed. Accordingly, the semiconductor memory device 100 of FIGS. 2A to 2D or the semiconductor memory device 100a of FIG. 4 may be formed.

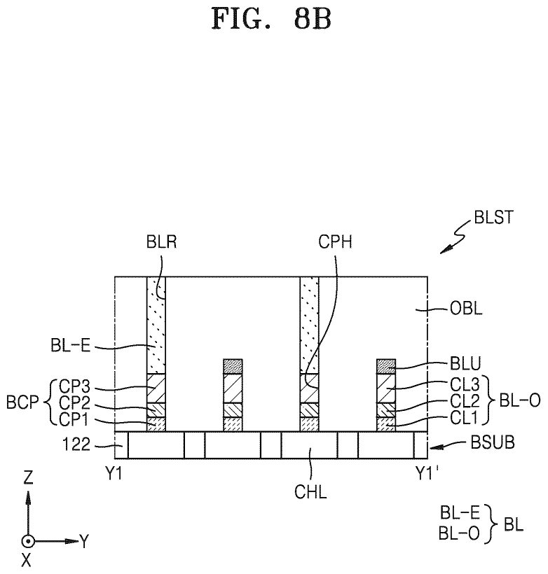

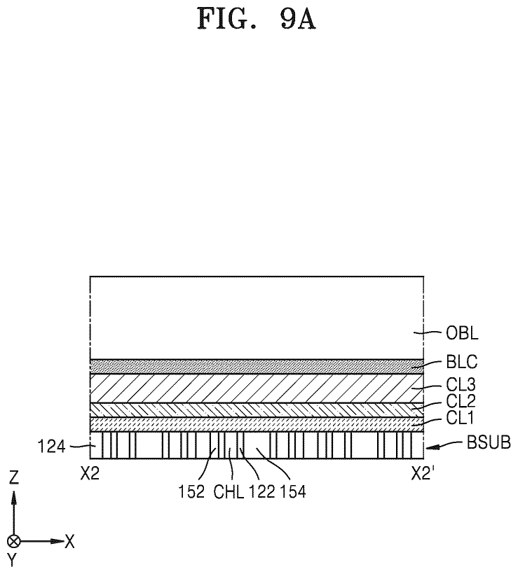

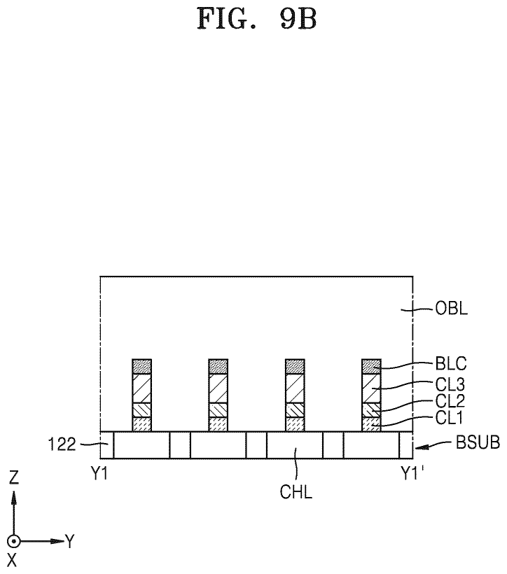

FIGS. 9A to 12B are cross-sectional views illustrating a method of manufacturing a bit line structure included in a semiconductor memory device, according to some example embodiments. In detail, FIGS. 9A, 10A, 11A, and 12A are respectively cross-sectional views illustrating a section cut along a portion corresponding to line X2-X2′ in FIG. 1, and FIGS. 9B, 10B, 11B, and 12B are respectively cross-sectional views illustrating a section cut along a portion corresponding to line Y1-Y1′ in FIG. 1.

Referring to FIGS. 9A and 9B, a plurality of stack structures each including a first line pattern CL1, a second line pattern CL2, a third line pattern CL3, and an insulating capping line BLC may be formed on the base substrate structure BSUB. Thereafter, a first interlayer insulating layer OBL surrounding the stack structures each including the first line pattern CL1, the second line pattern CL2, the third line pattern CL3, and the insulating capping line BLC may be formed.

The stack structures each including the first line pattern CL1, the second line pattern CL2, the third line pattern CL3, and the insulating capping line BLC may extend lengthwise in the first horizontal direction (the X direction) and may be repeatedly arranged spaced apart from each other in the second horizontal direction (the Y direction).

In some example embodiments, the base substrate structure BSUB may correspond to the channel structure CHST in FIGS. 2A to 2D and FIG. 4. Each of the stack structures each including the first line pattern CL1, the second line pattern CL2, the third line pattern CL3, and the insulating capping line BLC may extend on channel patterns CHL arranged in a line in the first horizontal direction (the X direction). For example, each of a plurality of first line patterns CL1 may be in contact with channel patterns CHL arranged in a line in the first horizontal direction (the X direction). In some example embodiments, the base substrate structure BSUB may correspond to a base substrate without a channel structure CHST.

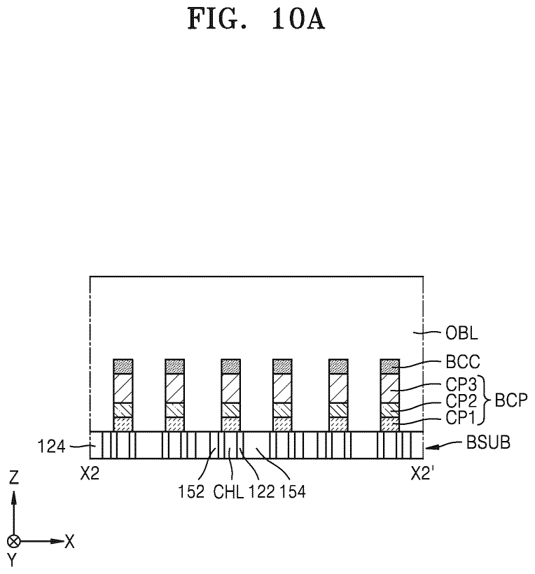

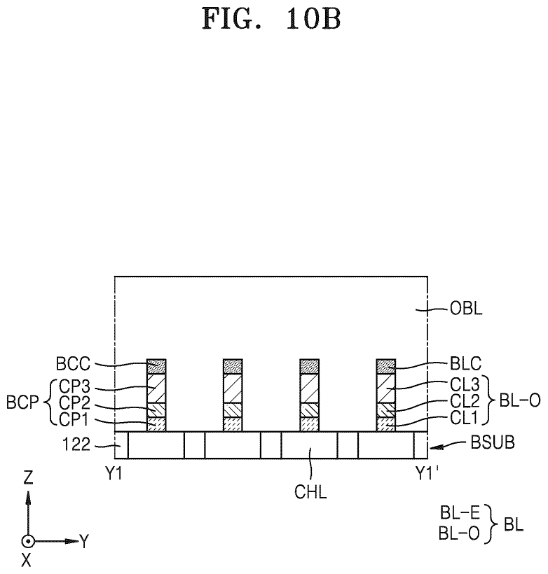

Referring to FIGS. 10A and 10B, among the stack structures each including the first line pattern CL1, the second line pattern CL2, the third line pattern CL3, and the insulating capping line BLC, one of two stack structures in a line in the second horizontal direction (the Y direction) may be alternately patterned, thereby forming a plurality of bit line contacts BCP. The bit line contacts BCP may be repeatedly arranged spaced apart from one another in the first horizontal direction (the X direction) and the second horizontal direction (the Y direction). Each of the bit line contacts BCP may have a stack structure of a first contact pattern CP1, a second contact pattern CP2, and a third contact pattern CP3. The first contact pattern CP1, the second contact pattern CP2, and the third contact pattern CP3 may correspond to remaining portions of the first line pattern CL1, the second line pattern CL2, and the third line pattern CL3, respectively, after the patterning. A plurality of insulating capping patterns BCC may be respectively disposed on the bit line contacts BCP. The insulating capping patterns BCC may respectively correspond to remaining portions of the insulating capping line BLC after the patterning.

Portions removed in the process of forming the bit line contacts BCP and the insulating capping patterns BCC may be replaced with an insulating material, which is the same as an insulating material included in the first interlayer insulating layer OBL, so that the first interlayer insulating layer OBL may cover the bit line contacts BCP and the insulating capping patterns BCC.

Referring to FIGS. 11A and 11B, a plurality of bit line recesses BLR extending downwards from the top surface of the first interlayer insulating layer OBL may be formed. The bit line recesses BLR may be formed by removing a portion of the first interlayer insulating layer OBL and the insulating capping patterns BCC in FIGS. 10A and 10B. The bit line contacts BCP, e.g., a plurality of third contact patterns CP3, may be exposed at the bottoms of the bit line recesses BLR. The bit line recesses BLR may extend lengthwise in the first horizontal direction (the X direction) and may be repeatedly arranged spaced apart from each other in the second horizontal direction (the Y direction). The top surfaces of bit line contacts BCP arranged in a line in the first horizontal direction (the X direction) and the first interlayer insulating layer OBL may be exposed at the bottom of each of the bit line recesses BLR.

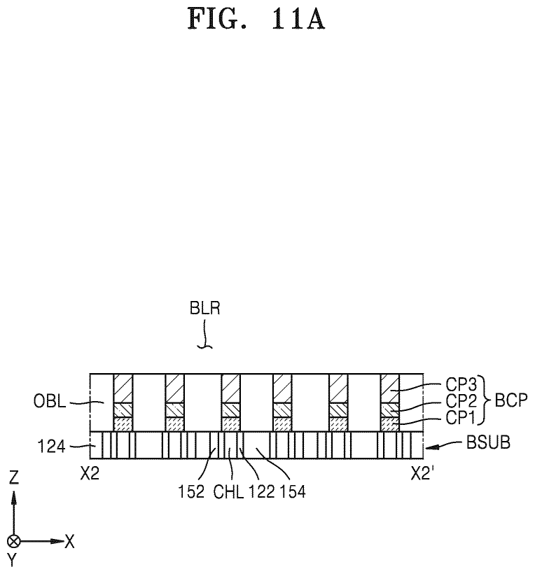

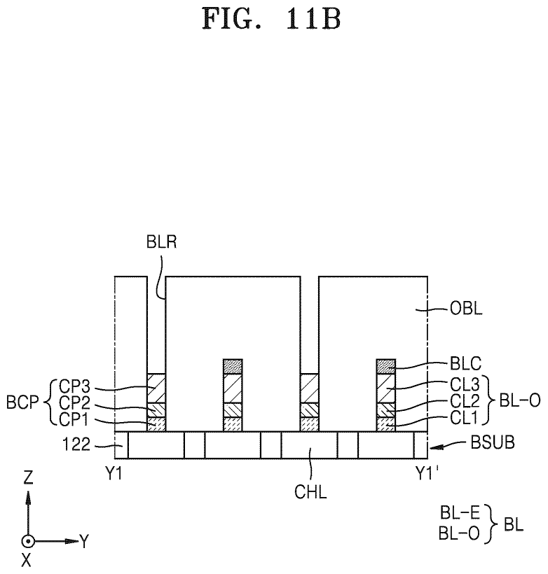

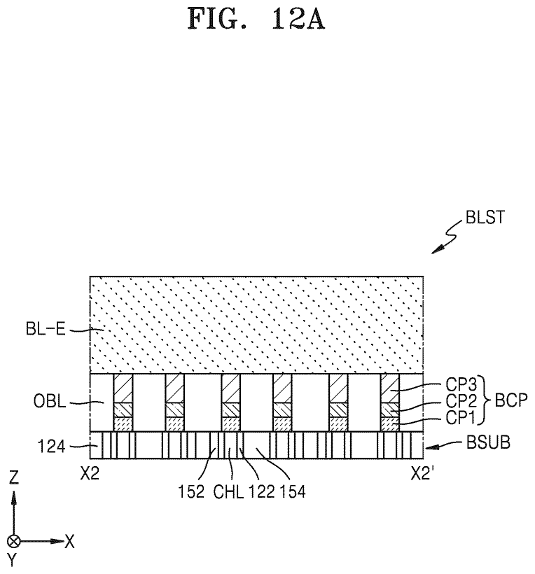

Referring to FIGS. 12A and 12B, a bit line structure BLST may be formed by forming a plurality of second bit lines BL-E filling the bit line recesses BLR. The second bit lines BL-E may extend lengthwise in the first horizontal direction (the X direction) and may be repeatedly arranged spaced apart from each other in the second horizontal direction (the Y direction). The second bit lines BL-E may be respectively formed on the bit line contacts BCP. Each of the second bit lines BL-E may be in contact with bit line contacts BCP arranged in a line in the first horizontal direction (the X direction) among the plurality of bit line contacts BCP.

The second bit lines BL-E may be formed by forming a conductive material layer, which fills the bit line recesses BLR and covers the first interlayer insulating layer OBL, and removing a portion of the conductive material layer covering the top surface of the first interlayer insulating layer OBL. In some example embodiments, in the process of removing the portion of the conductive material layer covering the top surface of the first interlayer insulating layer OBL, a portion of the conductive material layer filling upper portions of the bit line recesses BLR may be further removed. Thereafter, the cover capping lines BLCE in FIG. 4 may be formed by filling the upper portions of the bit line recesses BLR, from which the other portion of the conductive material layer is removed, with an insulating material.

In some example embodiments, after the second bit lines BL-E are formed, the capping layer CBL shown in FIGS. 2A to 2D may be formed.

Thereafter, as shown in FIGS. 2A to 2D or FIG. 4, after the first bonding insulating layer 166 is formed, the bit line structure BLST may be bonded to the peripheral circuit structure PRST on which the second bonding insulating layer 266 is formed, and the capacitor structure CTST may be formed on the channel structure CHST. Accordingly, the semiconductor memory device 100 of FIGS. 2A to 2D or the semiconductor memory device 100a of FIG. 4 may be formed. In some example embodiments, when the base substrate structure BSUB corresponds to a base substrate without the channel structure CHST, the first bonding insulating layer 166 may be formed as shown in FIGS. 2A to 2D or FIG. 4, and then, the bit line structure BLST may be bonded to the peripheral circuit structure PRST on which the second bonding insulating layer 266 is formed, the base substrate may be removed, and the channel structure CHST and the capacitor structure CTST may be formed. Accordingly, the semiconductor memory device 100 of FIGS. 2A to 2D or the semiconductor memory device 100a of FIG. 4 may be formed.

FIGS. 13A to 13D are cross-sectional views of the semiconductor memory device according to some example embodiments. In detail, FIG. 13A is a cross-sectional view taken along line X1-X1′ in FIG. 1, FIG. 13B is a cross-sectional view taken along line X2-X2′ in FIG. 1, FIG. 13C is a cross-sectional view taken along line Y1-Y1′ in FIG. 1, and FIG. 13D is a cross-sectional view taken along line Y2-Y2′ in FIG. 1.

Referring to FIGS. 13A to 13D, a semiconductor memory device 200 may include a memory cell region MCA in which a plurality of memory cells are arranged. The memory cell region MCA may be formed by stacking a capacitor structure CTST, a channel structure CHST, and a bit line structure BLST. In some example embodiments, the semiconductor memory device 200 may have a COP structure in which the memory cell region MCA overlaps a peripheral circuit structure PRST including a circuit gate structure 210 forming a peripheral circuit transistor in the vertical direction (the Z direction). In some example embodiments, the semiconductor memory device 200 may include a peripheral circuit region, which surrounds the memory cell region MCA in a plan view, instead of the peripheral circuit structure PRST. The peripheral circuit region may include a region in which the peripheral circuit transistor constituted of the circuit gate structure 210 is formed.

In some example embodiments, in the semiconductor memory device 200, the capacitor structure CTST, the channel structure CHST, and the bit line structure BLST may be sequentially stacked on the peripheral circuit structure PRST in the vertical direction (the Z direction). The bit line structure BLST may include a plurality of bit lines BL. The channel structure CHST may include a plurality of channel patterns CHL, a plurality of word lines WL, and a plurality of back gate electrodes BG. The capacitor structure CTST may include a plurality of contact plugs 130 and a plurality of capacitors 140.

The capacitor structure CTST, the channel structure CHST, and the bit line structure BLST in FIGS. 13A to 13D have shapes of upside-down versions of the capacitor structure CTST, the channel structure CHST, and the bit line structure BLST in FIGS. 2A to 2D, and thus, detailed descriptions thereof are omitted.

In some example embodiments, the first bonding insulating layer 166 may be disposed on the upper electrode 146. For example, the first bonding insulating layer 166 may cover the top surface of the upper electrode 146. The second bonding insulating layer 266 may be disposed on the peripheral circuit structure PRST. The second bonding insulating layer 266 may be covalently bonded to the first bonding insulating layer 166. The capacitor structure CTST of the memory cell region MCA may be bonded to the peripheral circuit structure PRST by a hybrid bonding method.

FIGS. 14 to 17 are flowcharts of methods of manufacturing a semiconductor memory device, according to some example embodiments. FIGS. 14 to 17 may be described with reference to FIGS. 1 to 13D.

Referring to FIG. 14, a channel structure CHST may be formed in operation S100. The channel structure CHST may include a plurality of channel patterns CHL, a plurality of word lines WL, a plurality of back gate electrodes BG, a plurality of back gate dielectric films 112, a plurality of gate dielectric films 122, and various insulating patterns.

A bit line structure BLST may be formed on the channel structure CHST in operation S200. As described with reference to FIGS. 5A to 8B or FIGS. 9A to 12B, the bit line structure BLST may include the plurality of first bit lines BL-O, the plurality of insulating capping lines BLC, the plurality of bit line contacts BCP, the plurality of second bit lines BL-E, the first interlayer insulating layer OBL, and the capping layer CBL.

The channel structure CHST may be arranged above the bit line structure BLST by flipping the channel structure CHST and the bit line structure BLST on the channel structure CHST in operation S300, e.g., by protecting a surface of a first substrate upon which the channel structure CHST and the bit line structure BLST are formed and flipping the first substrate. Thereafter, a capacitor structure CTST including a plurality of contact plugs 130 and a plurality of capacitors 140 may be formed on the channel structure CHST in operation S400, thereby forming the semiconductor memory device 100 of FIGS. 2A to 2D or the semiconductor memory device 100a of FIG. 4.

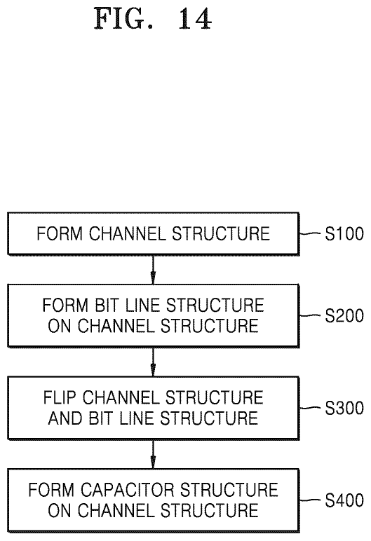

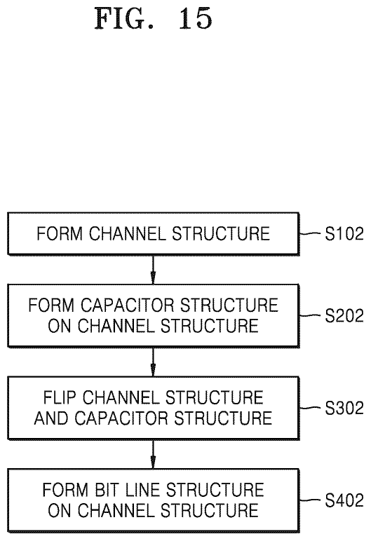

Referring to FIG. 15, a channel structure CHST may be formed in operation S102. The channel structure CHST may include a plurality of channel patterns CHL, a plurality of word lines WL, a plurality of back gate electrodes BG, a plurality of back gate dielectric films 112, a plurality of gate dielectric films 122, and various insulating patterns.

A capacitor structure CTST including a plurality of contact plugs 130 and a plurality of capacitors 140 may be formed on the channel structure CHST in operation S202.

The channel structure CHST may be arranged above the capacitor structure CTST by flipping the channel structure CHST and the capacitor structure CTST on the channel structure CHST in operation S302. Thereafter, a bit line structure BLST may be formed on the channel structure CHST in operation S402, thereby forming the semiconductor memory device 200 of FIGS. 13A to 13D. As described with reference to FIGS. 5A to 8B or FIGS. 9A to 12B, the bit line structure BLST may include the plurality of first bit lines BL-O, the plurality of insulating capping lines BLC, the plurality of bit line contacts BCP, the plurality of second bit lines BL-E, the first interlayer insulating layer OBL, and the capping layer CBL.

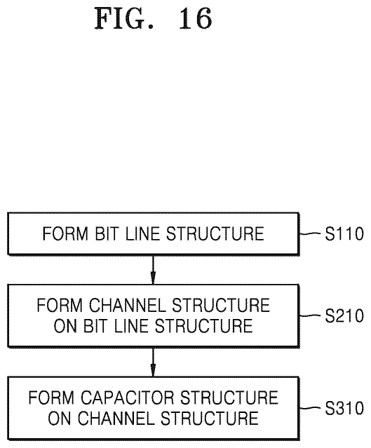

Referring to FIG. 16, a bit line structure BLST may be formed in operation S110. As described with reference to FIGS. 5A to 8B or FIGS. 9A to 12B, the bit line structure BLST may include the plurality of first bit lines BL-O, the plurality of insulating capping lines BLC, the plurality of bit line contacts BCP, the plurality of second bit lines BL-E, the first interlayer insulating layer OBL, and the capping layer CBL. In some example embodiments, the bit line structure BLST may be formed on a base substrate in which a channel structure CHST is not formed. The base substrate may correspond to a semiconductor substrate including a semiconductor material.

The channel structure CHST may be formed on the bit line structure BLST in operation S210. The channel structure CHST may include a plurality of channel patterns CHL, a plurality of word lines WL, a plurality of back gate electrodes BG, a plurality of back gate dielectric films 112, a plurality of gate dielectric films 122, and various insulating patterns.

Thereafter, a capacitor structure CTST including a plurality of contact plugs 130 and a plurality of capacitors 140 may be formed on the channel structure CHST in operation S310, thereby forming the semiconductor memory device 100 of FIGS. 2A to 2D or the semiconductor memory device 100a of FIG. 4.

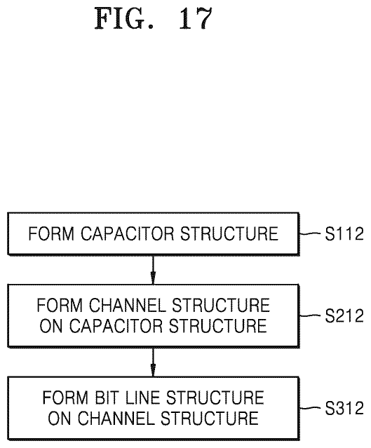

Referring to FIG. 17, a capacitor structure CTST including a plurality of contact plugs 130 and a plurality of capacitors 140 may be formed in operation S112.

A channel structure CHST may be formed on the capacitor structure CTST in operation S212. In some example embodiments, before the channel structure CHST is formed, the capacitor structure CTST may be flipped such that the contact plugs 130 face upwards. For example, the capacitor structure CTST that has been flipped may be temporarily attached to a handling substrate. The channel structure CHST may include a plurality of channel patterns CHL, a plurality of word lines WL, a plurality of back gate electrodes BG, a plurality of back gate dielectric films 112, a plurality of gate dielectric films 122, and various insulating patterns.

A bit line structure BLST may be formed on the channel structure CHST in operation S312, thereby forming a semiconductor memory device. As described with reference to FIGS. 5A to 8B or FIGS. 9A to 12B, the bit line structure BLST may include the plurality of first bit lines BL-O, the plurality of insulating capping lines BLC, the plurality of bit line contacts BCP, the plurality of second bit lines BL-E, the first interlayer insulating layer OBL, and the capping layer CBL.

In some example embodiments, when a stack structure including the capacitor structure CTST, the channel structure CHST, and the bit line structure BLST is flipped and bonded to the peripheral circuit structure PRST, the semiconductor memory device 100 of FIGS. 2A to 2D or the semiconductor memory device 100a of FIG. 4 may be formed. In some example embodiments, when a stack structure including the capacitor structure CTST, the channel structure CHST, and the bit line structure BLST is bonded to the peripheral circuit structure PRST, the semiconductor memory device 200 of FIGS. 13A to 13D may be formed.

While some example embodiments have been particularly shown and described with reference to some example embodiments thereof, it will be understood that various changes in form and details may be made therein without departing from the spirit and scope of the following claims. Additionally, example embodiments are not necessarily mutually exclusive with one another. For example, some example embodiments may include one or more features described with reference to one or more figures, and may also include one or more other features described with reference to one or more other figures.

What is claimed is:

1. A semiconductor memory device comprising:
a bit line structure including a plurality of bit lines and a plurality of bit line contacts, the plurality of bit lines extending in a first horizontal direction and spaced apart from each other in a second horizontal direction perpendicular to the first horizontal direction;
a capacitor structure including a plurality of contact plugs and a plurality of capacitors, the plurality of capacitors including a plurality of lower electrodes connected to the plurality of contact plugs, an upper electrode on the plurality of lower electrodes, and a capacitor dielectric film between the plurality of lower electrodes and the upper electrode; and
a channel structure including a plurality of vertical channel transistors, the plurality of vertical channel transistors including a plurality of channel patterns, a plurality of word lines, and a plurality of back gate electrodes, the plurality of channel patterns between the plurality of bit lines and the plurality of bit line contacts and extending in a vertical direction, and the plurality of word lines and the plurality of back gate electrodes extending in the second horizontal direction between the plurality of bit lines and the plurality of bit line contacts and having the plurality of channel patterns among the plurality of word lines and the plurality of back gate electrodes,
wherein the bit line structure, the capacitor structure, and the channel structure are stacked,
the plurality of bit lines include a plurality of first bit lines connected to some of the plurality of channel patterns and a plurality of second bit lines connected to other channel patterns of the plurality of channel patterns, the plurality of first bit lines and the plurality of second bit lines alternating in the second horizontal direction in a plan view,
at least a portion of each of the plurality of first bit lines and at least a portion of each of the plurality of second bit lines are at different vertical levels, and
the plurality of bit line contacts are at a same vertical level as at least the portion of each of the plurality of first bit lines and connect the plurality of second bit lines to the other channel patterns.

2. The semiconductor memory device of claim 1, wherein
the plurality of channel patterns are repeatedly arranged spaced apart from one another in the first horizontal direction and the second horizontal direction and are arranged in a plurality of lines in the second horizontal direction, and
the plurality of lines of the plurality of channel patterns alternately connect to the plurality of first bit lines and the plurality of second bit lines.

3. The semiconductor memory device of claim 1, wherein
each of the plurality of first bit lines has a stack structure of a first line pattern, a second line pattern, and a third line pattern, and
each of the plurality of bit line contacts has a stack structure of a first contact pattern, a second contact pattern, and a third contact pattern.

4. The semiconductor memory device of claim 3, wherein
the first line pattern is at a same vertical level as the first contact pattern, the second line pattern is at a same vertical level as the second contact pattern, and at least a portion of the third line pattern is at a same vertical level as the third contact pattern.

5. The semiconductor memory device of claim 3, wherein
the first contact pattern includes a same material as the first line pattern, the second contact pattern includes a same material as the second line pattern, and the third contact pattern includes a same material as the third line pattern.

6. The semiconductor memory device of claim 3, further comprising
an insulating capping line covering each of the plurality of first bit lines and in contact with the third line pattern,
wherein each of the plurality of second bit lines is in contact with the third contact pattern.

7. The semiconductor memory device of claim 1, wherein
the bit line structure further includes a first interlayer insulating layer surrounding the plurality of bit lines and the plurality of bit line contacts and filling all space between the plurality of bit lines, and
the capacitor structure further includes a second interlayer insulating layer surrounding the plurality of contact plugs.

8. The semiconductor memory device of claim 1, further comprising
a peripheral circuit structure at least partially overlapped by a memory cell region corresponding to the bit line structure, the capacitor structure, and the channel structure, the peripheral circuit structure including a peripheral circuit transistor.

9. The semiconductor memory device of claim 8, wherein
the bit line structure, the channel structure, and the capacitor structure are sequentially stacked on the peripheral circuit structure in the vertical direction.

10. The semiconductor memory device of claim 8, wherein
the capacitor structure, the channel structure, and the bit line structure are sequentially stacked on the peripheral circuit structure in the vertical direction.

11. A semiconductor memory device comprising:
a plurality of bit lines extending in a first horizontal direction and spaced apart from each other in a second horizontal direction perpendicular to the first horizontal direction, the plurality of bit lines including a plurality of first bit lines and a plurality of second bit lines alternating with the plurality of first bit lines in the second horizontal direction in a plan view;
a plurality of bit line contacts connected to the plurality of second bit lines;
a plurality of word lines on the plurality of bit lines and the plurality of bit line contacts and extending in the second horizontal direction;
a plurality of back gate electrodes separated from the plurality of word lines and extending in the second horizontal direction;
a plurality of channel patterns between a word line among the plurality of word lines and a back gate electrode among the plurality of back gate electrodes and having a first end and a second end opposite to the first end, the plurality of channel patterns each extending in a vertical direction, the word line and the back gate electrode adjacent to each other, and the second end connected to one of the plurality of first bit lines or one of the plurality of bit line contacts;
a plurality of contact plugs each connected to the first end of each of the plurality of channel patterns; and
a plurality of capacitors including a plurality of lower electrodes connected to the plurality of contact plugs, an upper electrode on the plurality of lower electrodes, and a capacitor dielectric film between the plurality of lower electrodes and the upper electrode.

12. The semiconductor memory device of claim 11, wherein
the plurality of channel patterns are repeatedly arranged and spaced apart from one another in the first horizontal direction and the second horizontal direction and arranged in a plurality of lines in the second horizontal direction,
channel patterns in one line among the plurality of lines are connected to one of the plurality of first bit lines, and
channel patterns in another line adjacent to the one line among the plurality of lines in the second horizontal direction are each connected to one of the plurality of second bit lines through one of the plurality of bit line contacts.

13. The semiconductor memory device of claim 11, wherein
a first horizontal width of each of the plurality of bit line contacts in the second horizontal direction is equal to a second horizontal width of each of the plurality of second bit lines in the second horizontal direction.

14. The semiconductor memory device of claim 11, wherein
a first horizontal width of each of the plurality of bit line contacts in the second horizontal direction is less than a second horizontal width of each of the plurality of second bit lines in the second horizontal direction.

15. The semiconductor memory device of claim 11, wherein
a first horizontal width of each of the plurality of bit line contacts in the second horizontal direction is greater than a second horizontal width of each of the plurality of second bit lines in the second horizontal direction.

16. The semiconductor memory device of claim 11, further comprising:
a plurality of insulating capping lines covering the plurality of first bit lines,
wherein each of the plurality of first bit lines has a stack structure of a first line pattern, a second line pattern, and a third line pattern,
each of the plurality of insulating capping lines is in contact with the third line pattern of each of the plurality of first bit lines,
each of the plurality of bit line contacts has a stack structure of a first contact pattern, a second contact pattern, and a third contact pattern, and
each of the plurality of second bit lines is in contact with the third contact pattern of each of the plurality of bit line contacts.

17. The semiconductor memory device of claim 16, wherein
the first line pattern and the first contact pattern include a same first material and are at a same vertical level, the second line pattern and the second contact pattern include a same second material and are at a same vertical level, the third line pattern and the third contact pattern include a same third material,
at least a portion of the third line pattern is at a same vertical level as the third contact pattern,
the same first material is same as or different from the same second material,
the same first material is same as or different from the same third material, and
the same second material is same as or different from the same third material.

18. A semiconductor memory device comprising:
a bit line structure including a plurality of bit lines, a plurality of bit line contacts, and a first interlayer insulating layer, the plurality of bit lines extending in a first horizontal direction and spaced apart from each other in a second horizontal direction perpendicular to the first horizontal direction, the plurality of bit lines including a plurality of first bit lines and a plurality of second bit lines alternating with the plurality of first bit lines in the second horizontal direction in a plan view, the plurality of bit line contacts connected to the plurality of second bit lines, and the first interlayer insulating layer surrounding the plurality of bit lines and the plurality of bit line contacts and filling all space between the plurality of bit lines;
a capacitor structure including a plurality of contact plugs, a second interlayer insulating layer surrounding the plurality of contact plugs, and a plurality of capacitors including a plurality of lower electrodes connected to the plurality of contact plugs, an upper electrode on the plurality of lower electrodes, and a capacitor dielectric film between the plurality of lower electrodes and the upper electrode;
a channel structure including a plurality of vertical channel transistors, the plurality of vertical channel transistors including a plurality of channel patterns, a plurality of word lines, and a plurality of back gate electrodes, the plurality of channel patterns between the plurality of bit lines and the plurality of bit line contacts and extending in a vertical direction, and the plurality of word lines and the plurality of back gate electrodes extending in the second horizontal direction and having the plurality of channel patterns among the plurality of word lines and the plurality of back gate electrodes; and
a peripheral circuit structure at least partially overlapped by a memory cell region corresponding to the bit line structure, the capacitor structure, and the channel structure and including a peripheral circuit transistor,
wherein the bit line structure, the capacitor structure, the channel structure, and the peripheral circuit structure are stacked,
at least a portion of each of the plurality of first bit lines and at least a portion of each of the plurality of second bit lines are at different vertical levels, and
the plurality of bit line contacts are at a same vertical level as at least the portion of each of the plurality of first bit lines.

19. The semiconductor memory device of claim 18, wherein
the plurality of channel patterns are repeatedly arranged spaced apart from one another in the first horizontal direction and the second horizontal direction and arranged in a plurality of lines in the second horizontal direction,
the plurality of lines of the plurality of channel patterns are alternately connected to the plurality of first bit lines and the plurality of second bit lines, and channel patterns in lines among the plurality of lines are connected to the plurality of second bit lines through the plurality of bit line contacts.

20. The semiconductor memory device of claim 18, wherein
the bit line structure, the channel structure, and the capacitor structure are sequentially stacked on the peripheral circuit structure in the vertical direction.
